(19) United States
(12) Patent Application Publication
(10) Pub. No.: US 2010/0236822 A1
(43) Pub. Date: Sep. 23, 2010

(54) WIRING BOARD AND METHOD FOR MANUFACTURING THE SAME

(75) Inventors: Toshiki FURUTANI, Ogaki-shi (JP); Takeshi FURUSAWA, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/498,860

(22) Filed: Jul. 7, 2009

Related U.S. Application Data
(60) Provisional application No. 61/162,464, filed on Mar. 23, 2009.

(51) Int. Cl. H05K 1/18; H05K 3/30

(52) U.S. Cl. 174/260; 29/832

(57) ABSTRACT

A wiring board is formed with a substrate, conductive patterns laminated in the thickness direction of the substrate, multiple pads having a predetermined pitch and formed on the same layer as the conductive patterns, a conductive bonding layer arranged on each of the multiple pads, and an electronic component having electrodes. Here, the electronic component is arranged inside the substrate. The electrodes of the electronic component and the multiple pads are electrically connected to each other by means of bonding layers. Also, the height of each of the multiple pads is greater than the height of the conductive pattern adjacent to each pad. Moreover, a protective material related to the bonding layers is not formed at least on the layer where the pads and the first conductive patterns are formed.

### CROSS-REFERENCE TO RELATED APPLICATIONS

The present application claims the benefits of priority to U.S. Application No. 61/162,464, filed Mar. 23, 2009. The contents of that application are incorporated herein by reference in their entirety.

### BACKGROUND OF THE INVENTION

1. Field of the Invention

The present invention is related to a wiring board with an electronic component such as an IC chip arranged inside, and its manufacturing method.

2. Discussion of the Background

For example, in Japanese Laid-Open Patent Publication 2004-7006, a wiring board with a built-in electronic component is described in which the electronic component is built into a space formed in a resin substrate. In such a wiring board, the electronic component is mounted on a wiring layer made of metal foil.

Also, in Japanese Laid-Open Patent Publication 2000-22318, a wiring board is described where a solder-resist layer with opening portions is formed as an outermost layer. A solder-resist layer is used to prevent solder from adhering around pads, to maintain insulation between pads, to protect pads and so forth. In the opening portions of such a solder-resist layer, solder bumps are formed. Then, a semiconductor element or the like is surface-mounted by means of the solder bumps.

The contents of these publications are incorporated herein by reference in their entirety.

### SUMMARY OF THE INVENTION

A wiring board according to one aspect of the present invention has a substrate, a first conductive pattern formed on a surface of or inside the substrate, multiple pads with a predetermined pitch formed on the same layer as the first conductive pattern, conductive bonding layers arranged on each of the multiple pads, and an electronic component having electrodes. In such a wiring board, the electronic component is arranged inside the substrate, the electrodes of the electronic component and the multiple pads are electrically connected by means of the bonding layers, the height of each of the multiple pads is greater than the height of the first conductive pattern adjacent to the pad, and a protective material related to the bonding layers is not formed at least on the layer where the multiple pads and the first conductive pattern are formed.

“Arranged inside the substrate” includes cases in which the entire electronic component is completely embedded inside the substrate, as well as cases in which part of the electronic component is arranged in a recessed section formed in the substrate. In short, it is sufficient for at least part of the electronic component to be arranged inside the substrate. Also, the “height” of a pad or conductive pattern indicates the maximum height. Namely, if the height is not made uniform, for example, when the bottom is flat but the top surface is slanted, or when there is a cavity formed on the top, the difference measured from the highest point of the top to the bottom is referred to as “height.”

A method for manufacturing a wiring board according to another aspect of the present invention is as follows: a step to form a first resist layer having a first opening portion and a second opening portion on a predetermined layer; a step to form a conductive pattern in the first opening of the first resist layer and a first pad in the second opening portion of the first resist layer; a step to form on the first resist layer a second resist layer which coats the conductive pattern and has an opening portion on the first pad; a step to form a second pad in the opening portion of the second resist layer; a step to remove the first resist layer and the second resist layer; after the fourth step, a sixth step to form a bonding layer on the second pad; and a step to electrically connect an electrode of an electronic component and the second pad by means of a bonding layer.

The foregoing steps may be conducted in any order unless otherwise specified. For example, the sixth step may be conducted before the fifth step.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a wiring board according to an embodiment of the present invention;

FIG. 2 is a plan view showing a component mounting section of the wiring board in FIG. 1;

FIG. 3 is a cross-sectional view taken from the A-A line in FIG. 2;

FIG. 4A is a cross-sectional view taken from the B-B line in FIG. 2;

FIG. 4B is a cross-sectional view taken from the C-C line in FIG. 2;

FIG. 4C is a cross-sectional view taken from the D-D line in FIG. 2;

FIG. 5 is a photograph showing the area of connection terminals in an example of a wiring board;

FIG. 6 is a photograph magnifying part of FIG. 5;

FIG. 7A is a view illustrating the results of warping simulations in a wiring board;

FIG. 7B is a view illustrating the results of warping simulations in a wiring board;

FIG. 8A is a view illustrating a step to prepare a first support base material;

FIG. 8B is a view illustrating a step to prepare a seed layer;

FIG. 9A is a view illustrating a step to prepare a first resist layer;

FIG. 9B is a view illustrating a step to pattern the first resist layer;

FIG. 9C is a view illustrating a step to form conductive patterns and pads;

FIG. 10A is a view illustrating a step to prepare a second resist layer;

FIG. 10B is a view illustrating a step to pattern the second resist layer;

FIG. 10C is a view illustrating a step to form second pads;

FIG. 10D is a view illustrating a step to remove the first resist layer and the second resist layer;

FIG. 11A is a view illustrating a step to form bonding layers;

FIG. 11B is a view illustrating a step to mount an electronic component;

FIG. 11C is a view illustrating a step to form underfill material;

FIG. 12A is a view illustrating a step to arrange an electronic component in the substrate;

FIG. 12B is a view illustrating a step to prepare a second support substrate;

FIG. 13A is a view illustrating a step to pressurize the substrate;

FIG. 13B is a view illustrating a step to remove (separate) a carrier;

FIG. 14A is a view illustrating a step to form through-holes;

FIG. 14B is a view illustrating a step to form conductors on both surfaces of the substrate and inner walls of the through-holes;

FIG. 15A is a view illustrating a step to form resist layers;

FIG. 15B is a view illustrating a step to thicken the portions of the conductors that correspond to conductive patterns and through-hole conductors;

FIG. 15C is a view illustrating a step to pattern first base layers, second base layers and conductive patterns;

FIG. 16A is a view illustrating a step to arrange insulation layers and copper foils;

FIG. 16B is a view illustrating a step to pressurize the substrate;

FIG. 17A is a view illustrating a step to form penetrating holes that penetrate interlayer insulation layers;

FIG. 17B is a view illustrating a step to perform conductive plating on both surfaces of the substrate;

FIG. 18A is a view illustrating a step to form resist layers;

FIG. 18B is a view illustrating a step to thicken the portions of the conductors that correspond to wiring layers;

FIG. 18C is a view illustrating a step to pattern the wiring layers;

FIG. 19A is a view showing a first example of another pad configuration;

FIG. 19B is a view showing a second example of yet another pad configuration;

FIG. 19C is a view showing a third example of yet another pad configuration;

FIG. 20 is a view showing a fourth example of yet another pad configuration;

FIG. 21 is a view showing another example of a method to connect connection terminals;

FIG. 22 is a view showing another example of a method to arrange connection terminals;

FIG. 23A is a cross-sectional view taken from the A-A line in FIG. 22;

FIG. 23B is a cross-sectional view taken from the B-B line in FIG. 22;

FIG. 24 is a view showing an example electrically connecting both surfaces of a wiring board by tapered filled vias;

FIG. 25A is a view illustrating a first step of an example to form the tapered filled vias;

FIG. 25B is a view illustrating a second step of the example to form the tapered filled vias;

FIG. 25C is a view illustrating a third step of the example to form the tapered filled vias;

FIG. 26 is a view showing an example electrically connecting both surfaces of a wiring board by hourglass-shaped filled vias;

FIG. 27A is a view illustrating a first step of an example to form the hourglass-shaped filled vias;

FIG. 27B is a view illustrating a second step of the example to form the hourglass-shaped filled vias;

FIG. 27C is a view illustrating a third step of the example to form the hourglass-shaped filled vias;

FIG. 28 is a view showing an example electrically connecting both surfaces of a wiring board by through-hole conductors without base layers;

FIG. 29A is a view illustrating a first step of an example to form through-hole conductors without base layers;

FIG. 29B is a view illustrating a second step of the example to form through-hole conductors without base layers;

FIG. 29C is a view illustrating a third step of the example to form through-hole conductors without base layers;

FIG. 30A is a view illustrating a first step of an example to form wiring layers by a semi-additive method;

FIG. 30B is a view illustrating a second step of the example to form wiring layers by a semi-additive method;

FIG. 30C is a view illustrating a third step of the example to form wiring layers by a semi-additive method;

FIG. 31A is a view illustrating a fourth step of the example to form wiring layers by a semi-additive method;

FIG. 31B is a view illustrating a fifth step of the example to form wiring layers by a semi-additive method; and

FIG. 31C is a view illustrating a sixth step of the example to form wiring layers by a semi-additive method.

### DETAILED DESCRIPTION OF THE EMBODIMENTS

The embodiments will now be described with reference to the accompanying drawings, wherein like reference numerals designate corresponding or identical elements throughout the various drawings.

In the following, a wiring board and its manufacturing method are described according to the embodiments of the present invention by referring to the drawings. In the drawings, arrows (Z1, Z2) indicate respectively the direction of lamination in a wiring board (the direction of the normal line to the main surfaces of the wiring board, or the direction of thickness of the core substrate). By contrast, arrows (X1, X2) and (Y1, Y2) indicate respectively the direction perpendicular to the lamination direction (horizontal to the main surfaces of the wiring board). In the following, two main surfaces of a wiring board are referred to as a first surface (the surface on the arrow-Z1 side) and a second surface (the surface on the arrow-Z2 side). In addition, in the direction of lamination, the side closer to the core (insulation layer 11) is referred to as a lower layer and the side farther from the core as an upper layer.

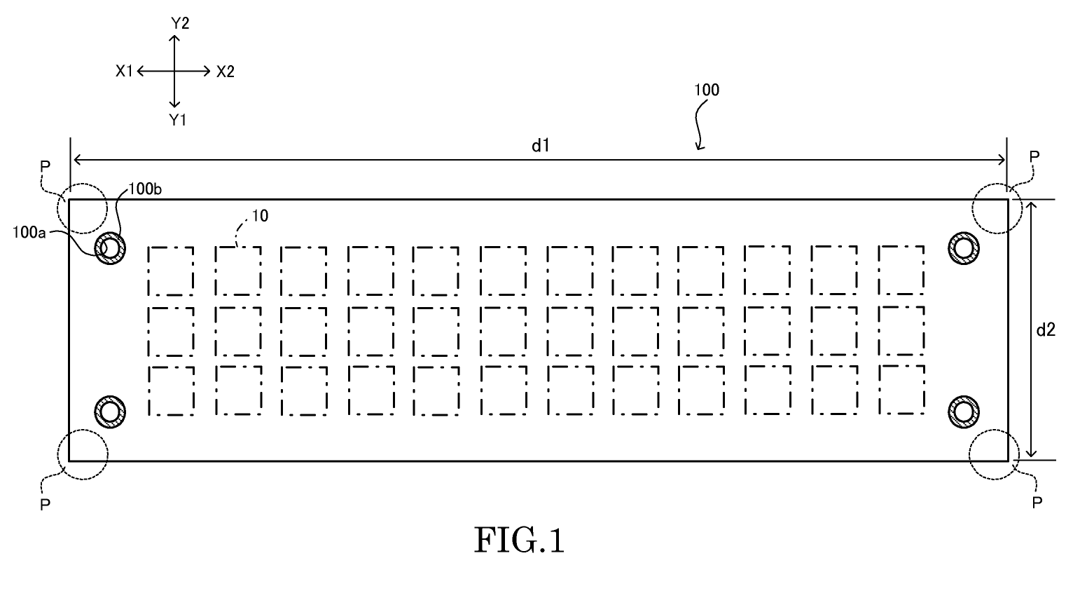

Wiring board 100 of the present embodiment is a rectangular multilayer printed wiring board as shown in FIG. 1. Penetrating holes (100a) are formed at its four corners, and inner-layer conductors (100b) are exposed on the periphery of penetrating holes (100a). Accordingly, stresses are mitigated by penetrating holes (100a), and heat dissipation is improved by conductors (100b). Longitudinal width (d1) of wiring board 100 is 230 mm, for example; and latitudinal width (d2) of wiring board 100 is 60 mm, for example. Wiring board 100 has multiple component mounting sections 10. Component mounting sections 10 are set in a grid array. The configuration and dimensions, etc., of wiring board 100 may be modified according to usage requirements or the like.

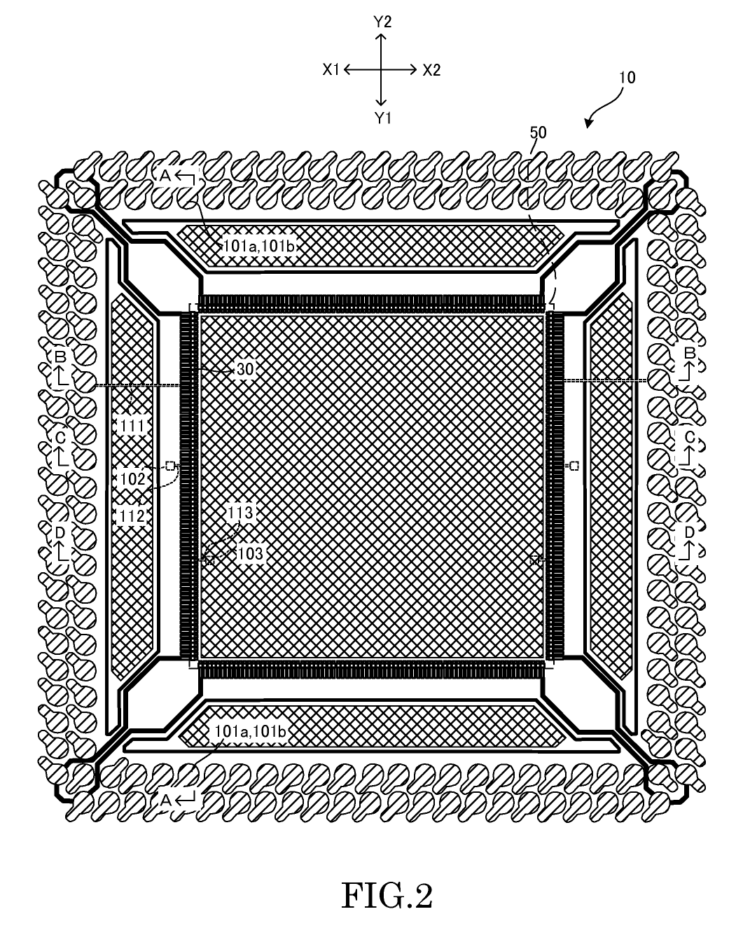

FIG. 2 is a view showing the connection method of part of connection terminals 30.

In wiring board 100, electronic component 50 is built into each component mounting section 10, as shown in FIG. 2. Connection terminals 30 of wiring board 100 are arranged in a peripheral array. Namely, each connection terminal 30 is electrically connected to each terminal of electronic component 50 on the outer periphery of electronic component 50. Among those, predetermined connection terminal 30 is electrically connected to through-hole lands (101a, 101b) on both surfaces of wiring board 100 by means of lead wire 111. Another predetermined connection terminal 30 is electrically connected to external pad 102 by means of lead wire 112. Yet another predetermined connection terminal 30 is electrically connected to an interior pad by means of lead wire 113. By diversifying the connection method as such, even if each connection terminal 30 is formed with fine pitch, wiring space between connection terminals may be ensured.

The connection method of connection terminals 30 is not limited to the above; any other methods may be employed. For example, connection terminals 30 may be connected to only one or any two of the following: lands (through-hole lands 101a, 101b), external terminals (pads 102) and interior terminals (pads 103).

Since wiring board 100 has electronic component 50 accommodated (built) into it, other electronic components or the like may be mounted on the surface mounting regions. As a result, high functionality may be achieved. Arranging connection terminals is not limited to a peripheral array, and an area array may also be employed. Wiring board 100 is not limited to having multiple units (component mounting sections 10), but may have only a single unit. Also, after multiple units are formed on a single substrate (sheet) and inspected, each unit may be separated from the substrate.

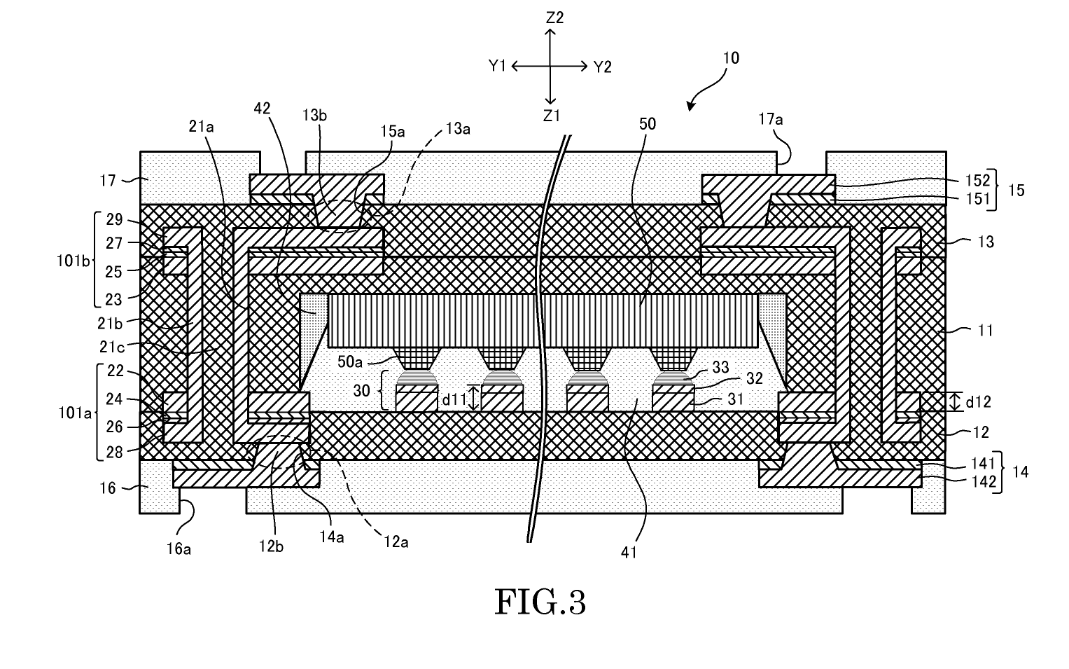

As shown in FIG. 3 (cross-sectional view taken from the A-A line in FIG. 2), FIG. (4A) (cross-sectional view taken from the B-B line in FIG. 2), FIG. (4B) (cross-sectional view taken from the C-C line in FIG. 2), and FIG. (4C) (cross-sectional view taken from the D-D line in FIG. 2), component mounting section 10 is formed, in addition to electronic component 50, with insulation layers (11-13), wiring layers (14, 15), solder-resist layers (16, 17), underfill 41, filler 42, inner-layer conductive patterns (22, 23), external-layer conductive patterns (28, 29), connection terminals 30 and through-hole conductors (21b).

Electronic component 50 has multiple bumps (50a) for flip-chip mounting. Bumps (50a) are arranged in a peripheral array, for example. Bumps (50a) are gold-stud bumps with an approximate thickness of 30 μm, for example. On one side of electronic component 50, for example, on its first surface, bumps (50a) and predetermined circuits are formed. Electronic component 50 is flip-chip mounted. In doing so, wiring board 100 may be made thinner (more compact). As for electronic component 50, other than active components such as IC chips, any type of electronic components, for example, passive components such as capacitors, resistors or coils, may be used. In addition, arranging bumps (50a) of electronic component 50 is not limited to a peripheral array, and an area array may also be employed.

In wiring board 100, insulation layers (11-13) correspond to a substrate. Electronic component 50 is arranged inside such a substrate. Through-hole conductor (21b) is formed on the inner wall of through-hole (21a) that penetrates insulation layer 11. Insulation layer 12 is formed on the first surface of insulation layer 11; and insulation layer 13 is formed on the second surface of insulation layer 11. Insulation layer 12 and insulation layer 13 are connected to each other by means of insulation layer (21c) in through-hole (21a).

Through-hole lands (101a, 101b) are formed on the periphery of through-hole (21a). In doing so, the electrical connection of through-hole conductor (21b) or the like will be enhanced. Through-hole land (101a) is formed by laminating conductive pattern 22 (first inner layer), first base layer 24, second base layer 26 and conductive pattern 28 (first external layer); and through-hole land (101b) is formed by laminating conductive pattern 23 (second inner layer), first base layer 25, second base layer 27 and conductive pattern 29 (second external layer). Through-hole land (101a) and through-hole land (101b) are electrically connected to each other by means of through-hole conductor (21b).

Insulation layers (11-13) and (21c) are each made from board-type cured prepreg. Such prepreg is preferred to contain reinforcing material such as glass fiber or aramid fiber, which is then impregnated with resin. Such a reinforcing material has a smaller coefficient of thermal expansion than the primary material (prepreg).

The configuration, material, etc., of insulation layers (11-13) and (21c) may be modified according to usage requirements or other requirements. For example, as for prepreg, the following may also be used: base material such as glass fiber or aramid fiber impregnated with resin such as epoxy resin, polyester resin, bismaleimide triazine (BT) resin, imide resin (polyimide) or allyl polyphenylene ether resin (A-PPE resin). In addition, instead of prepreg, liquid or film-type thermosetting resins or thermoplastic resins, or resin-coated copper foil (RCF) may also be used. As for such thermosetting resins, for example, epoxy resin, imide resin (polyimide), BT resin, allyl polyphenylene ether resin, aramid resin or the like may be used. Also, as for thermoplastic resins, for example, liquid crystal polymer (LCP), PEEK resin, PTFE resin (fluororesin) or the like may be used. Such resins are preferred to be selected according to requirements in view of insulation, dielectric properties, heat resistance and mechanical characteristics. In addition, such resins may contain additives such as curing agents, stabilizers or filler. Also, insulation layers (11-13) and (21c) may be formed with multiple layers made of different materials.

Underfill 41 is made from insulative thermosetting resin containing inorganic filler 40-90 wt. %. As for such inorganic filler, for example, silica, alumina or the like may be used. The size of filler (average particle diameter) is preferred to be set at 0.1-3.0 μm, for example. Underfill 41 enhances strength when securing electronic component 50. Also, underfill 41 absorbs warping caused by different thermal expansion coefficients between electronic component 50 and insulative material (such as insulation layer 11 and filler 42).

Filler 42 is made from insulative thermoseting resin containing inorganic filler. As for thermoseting resins, for example, resins with highly heat-resistant resins, such as epoxy resin, phenol resin or cyanate resin, are preferred. Among those, epoxy resin is especially preferred because of its excellent heat resistance. As for inorganic fillers, for example, Al₂O₃, MgO, Bn, AlN or SiO₂ may be used.

Areas surrounding electronic component 50 are coated with insulative material (insulation layer 11, underfill 41 and filler 42). Thus, electronic component 50 is strongly secured. As a result, during a multilayer process such as a building up process, it is easy to handle the substrate. Also, since electronic component 50 is enveloped by insulative material, adverse effects on electronic component 50 such as seeping etchants during the manufacturing process will decrease. Furthermore, electronic component 50 becomes resistant to stresses caused by heat, by impact from vibration or from being dropped, and so forth.

Conductive pattern 22 is formed inside (hereinafter referred to as the first inner layer) the first-surface side (the arrow-Z1 side) of insulation layer 11. Conductive pattern 22 is made of copper, for example. The thickness of conductive pattern 22 is set at 18 μm, for example. Part of conductive pattern 22 is used as through-hole land (101a) (first inner layer).

Conductive pattern 23 is formed opposite the first inner layer, namely, inside (hereinafter referred to as the second inner layer) the second-surface side (the arrow-Z2 side) of insulation layer 11. Conductive pattern 23 is made of copper, for example. The thickness of conductive pattern 23 is set at 18 μm, for example. Part of conductive pattern 23 is used as through-hole land (101b) (second inner layer).

Since conductive patterns (22, 23) are formed in areas surrounding electronic component 50, the substrate in the area surrounding electronic component 50 is suppressed from warping.

Conductive pattern 28 is formed on the first surface (hereinafter referred to as first external layer) of insulation layer 11. First base layer 24 and second base layer 26 are formed as base layers of conductive pattern 28. Such first base layer 24, second base layer 26 and conductive pattern 28 are laminated on conductive pattern 22 in that order. First base layer 24 is made of a metal such as nickel; and second base layer 26 is made of copper foil, for example. Conductive pattern 28 is made of copper, for example. The thickness of conductive pattern 28 is approximately 20 μm, for example.

Conductive pattern 29 is formed opposite the first external layer, namely, on the second surface (hereinafter referred to as the second external layer) of insulation layer 11. First base layer 25 and second base layer 27 are formed as base layers of conductive pattern 29. Such first base layer 25, second base layer 27 and conductive pattern 29 are laminated on conductive pattern 23 in that order. First base layer 25 is made of a metal such as nickel; and second base layer 27 is made of copper foil, for example. Conductive pattern 29 is made of copper, for example. The thickness of conductive pattern 29 is approximately 20 μm, for example.

Through-hole conductor (21b) and conductive pattern 28 or conductive pattern 29 are formed to be contiguous to each other from the inner wall of through-hole (21a) that penetrates insulation layer 11 to a surface of insulation layer 11 (first surface or second surface). Part of conductive pattern 28 is used as through-hole land (101a) (first external layer); and part of conductive pattern 29 is used as through-hole land (101b) (second external layer).

Wiring layer 14 is formed on the first surface of insulation layer 12; and wiring layer 15 is formed on the second surface of insulation layer 13. Wiring layer 14 is formed with first wiring layer 141 and second wiring layer 142; and wiring layer 15 is formed with first wiring layer 151 and second wiring layer 152. First wiring layers (141, 151) are made of copper foil, for example. Second wiring layers (142, 152) are formed of copper-plated film, for example. Since wiring layers (14, 15) contain first wiring layers (141, 151) (metal foil) and second wiring layers (142, 152) (plated-metal film), adhesiveness is enhanced between first wiring layers (141, 151) and insulation layers (12, 13) and delamination will seldom occur. The material, thickness, etc., of wiring layers (14, 15) may be modified according to usage requirements or the like.

In insulation layers (12, 13), tapered via holes (12a, 13a) are formed. More specifically, in insulation layers (12, 13) and first wiring layers (141, 151), tapered penetrating holes (14a, 15a) are formed to be connected to conductive patterns (28, 29). Via holes (12a, 13a) are formed as part of penetrating holes (14a, 15a) respectively. In addition, in penetrating holes (14a, 15a), conductors (12b, 13b) contiguous to second wiring layers (142, 152) are filled. Thus, conductors (12b, 13b) are also filled in via holes (12a, 13a), which are part of penetrating holes (14a, 15a) respectively. Via hole (12a) and conductor (12b) as well as via hole (13a) and conductor (13b) each form a filled via. Conductive patterns (28, 29) and wiring layers (14, 15) are electrically connected by means of such filled vias. By employing filled vias, the rigidity of the wiring board increases and warping may be suppressed. Moreover, since via holes may be stacked directly on filled vias, highly integrated wiring may be achieved while ample wiring spaces are ensured. The configuration of penetrating holes (14a, 15a) is not limited to being tapered, and any other configuration may be used. In addition, via holes (12a, 13a) are not limited to forming filled vias; they may also form conformal vias, for example.

On the first surface of insulation layer 12, solder-resist layer 16 with opening portions (16a) is formed. Also, on the second surface of insulation layer 13, solder-resist layer 17 with opening portions (17a) is formed. As such, wiring board 100 has solder-resist layers (16, 17) formed on both of its outermost surfaces (first surface and second surface), not only on one outermost surface. Thus, it may keep a symmetrical structure in regard to thermal expansion coefficients. As a result, warping caused by temperature changes or the like may be suppressed. Solder-resist layers (16, 17) are formed with, for example, photosensitive resins using acrylic-epoxy resin, thermosetting resins mainly containing epoxy resin, ultraviolet curing resins, or the like. Wiring layers (14, 15) are exposed through opening portions (16a, 17a).

Each connection terminal 30 is formed with first pad 31 made of, for example, the same material (such as copper) as conductive pattern 22, second pad 32 made of nickel, for example, and bonding layer 33 made of electrolytic solder-plated film, for example, which are laminated from the first-surface side in that order. First pad 31, second pad 32 and bonding layer 33 have pillar-like outer shapes. They are configured in a cylindrical shape, for example. However, configurations of first pad 31, second pad 32 and bonding layer 33 are not limited to such, and any other shape may be employed. Regarding the pillar-like outer shapes, the upper-layer surface is referred to as the top face and the lower-layer surface as the bottom face.

First pad 31 and conductive pattern 22 are arranged on the same surface (second surface of insulation layer 12). Among the surfaces of first pad 31, the surface which is not in contact with insulation layer 12 nor with second pad 32, namely, the side surface of first pad 31, is in contact with underfill 41. Also, among the surfaces of second pad 32, the surface which is not in contact with first pad 31 nor bonding layer 33, namely, the side surface of second pad 32, is in contact with underfill 41. As such, in the present embodiment, protective material (for example, solder resist) related to bonding layer 33 is not formed on at least the same layer that forms first pad 31 and conductive pattern 22.

Multiple connection terminals 30 each correspond to terminals for mounting an electronic component. Flip-chip mounting of electronic component 50 may be achieved using connection terminals 30. More specifically, conductive patterns (wiring layers 14, 15, etc.) of wiring board 100 and bumps (50a) of electronic component 50 are electrically connected by means of connection terminals 30. The thickness of first pad 31 is the same as the thickness of conductive pattern 22, for example, and is set at 18 μm, for example. The thickness of second pad 32 is set at 6 μm, for example, and the thickness of bonding layer 33 is set at 14 μm, for example.

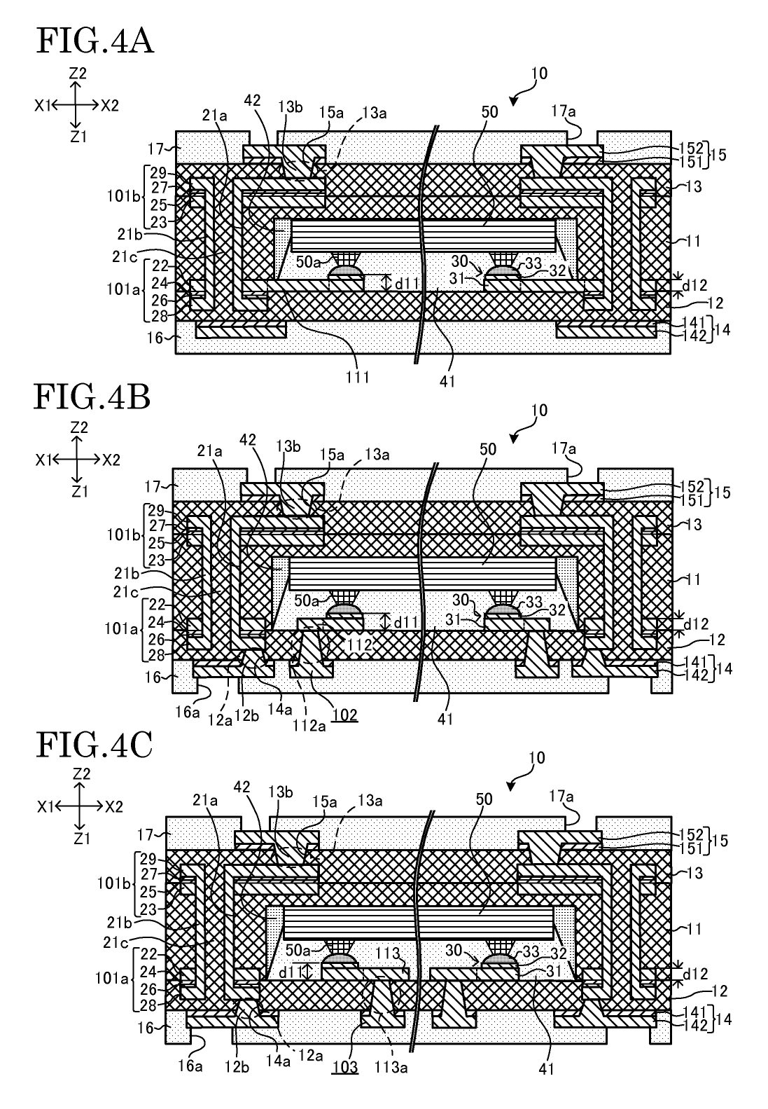

Predetermined connection terminal 30 is electrically connected to conductive pattern 22 by means of lead wire 111 as shown in FIG. 4A. First pad 31, lead wire 111 and conductive pattern 22 are formed with the same material on the same layer and are formed to be contiguous to each other. First pad 31 of another predetermined connection terminal 30 is distributed to the outside using lead wire 112 as shown in FIG. 4B. Lead wire 112 is electrically connected to upper-layer pad 102 by means of filled via (112a). First pad 31 and lead wire 112 are formed with the same material on the same layer and are formed to be contiguous to each other. Moreover, first pad 31 of yet another predetermined connection terminal 30 is distributed to the inside by means of lead wire 113 as shown in FIG. 4C. Lead wire 113 is electrically connected to upper-layer pad 103 by means of filled via (113a). First pad 31 and lead wire 113 are formed with the same material on the same layer and are formed to be contiguous to each other. Interlayer connection is not limited to any specific type; conformal vias may be used instead of filled via (112a) or (113a).

By forming second pad 32 on first pad 31, the total height of first pad 31 and second pad 32, namely, height (d11) of the pad becomes greater than height (d12) of conductive pattern 22. In doing so, even if conductive pattern 22 is not coated with a protective material (for example, solder resist) related to bonding layer 33, bonding layer 33 (for example, solder) will not adhere to conductive pattern 22, and may adhere selectively to second pad 32. Also, second pad 32 has a higher level of wettability with the material (for example, solder) of bonding layer 33 than either first pad 31 or conductive pattern 22. By enhancing wettability using second pad 32, bonding layer 33 will adhere selectively to each second pad 32. Since it is easier to adhere bonding layer 33 selectively to second pad 32 when forming bonding layer 33, wiring board 100 does not require protective material (such as solder resist) for connection terminals 30. Accordingly, stress may be mitigated, and warping may be suppressed from occurring in the substrate (will be described later in detail). As the material for second pad 32, other than nickel, metals such as gold may also be used.

Bonding layer 33 is made with a material, for example, different from that of either first pad 31 or second pad 32. Bonding layer 33 is made with solder, or a metal such as tin, nickel, metal or plated-metal film of alloys of such metals. Alternatively, bonding layer 33 may be formed not by plating, but by printing, for example, solder paste and reflowing it. Moreover, bonding layer 33 may be a complex layer formed by combining different layers. However, the outermost surface of bonding layer 33 is preferred to be made of solder.

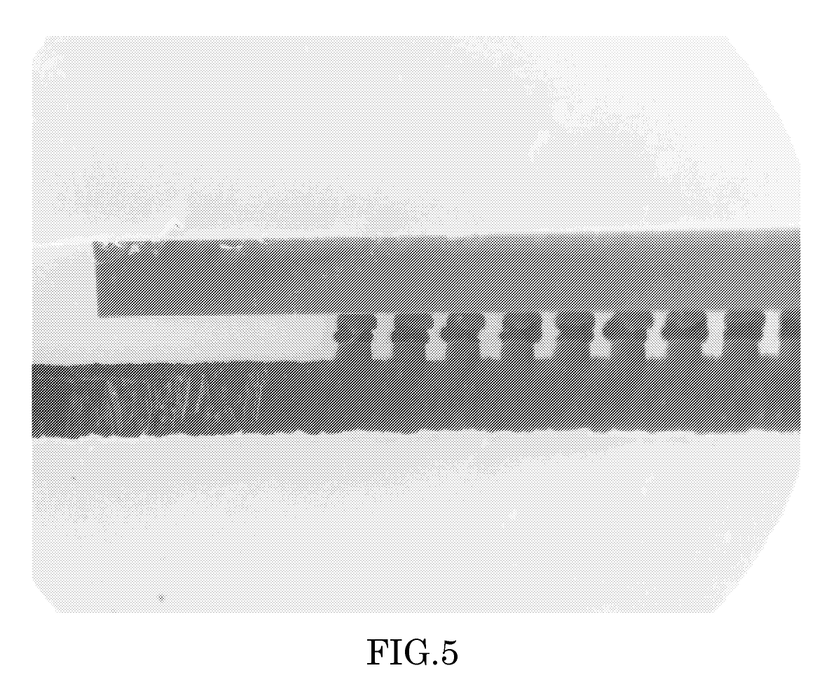

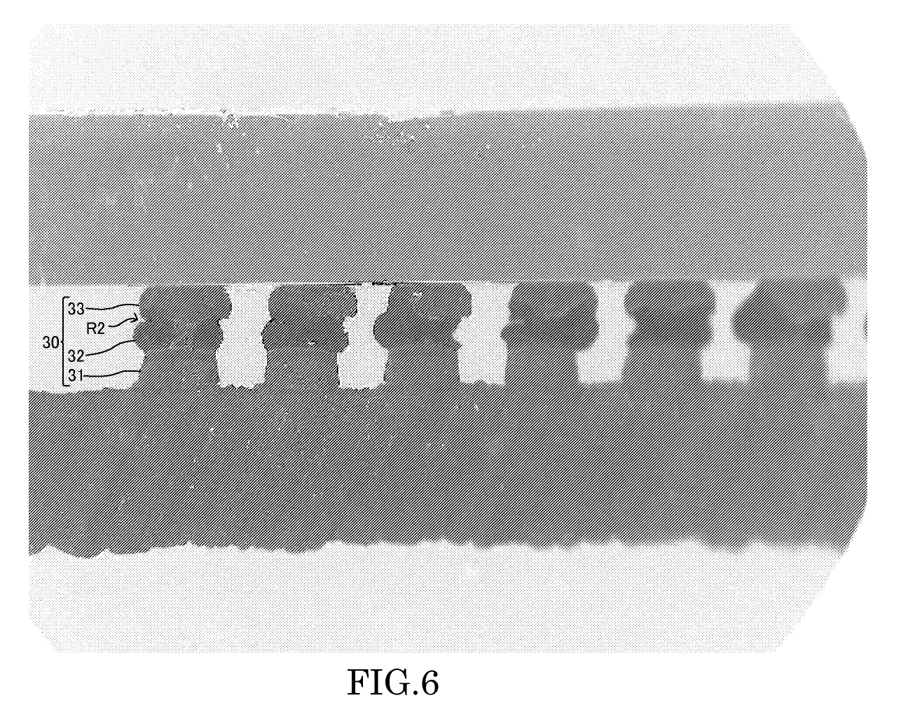

Photographs of an example of wiring board 100 are provided for reference. FIG. 5 is a photograph showing the area surrounding connection terminals 30, and FIG. 6 is a photograph magnifying part of FIG. 5. First pad 31 and second pad 32 have the same width as bonding layer 33 at their boundary surface, namely, at top face (R2) of second pad 32. Bonding layer 33 makes contact only with top face (R2) of second pad 32, and does not touch the side surfaces of first pad 31 or second pad 32. Accordingly, even if adjacent connection terminals are formed with a fine pitch, insulation between them may be ensured.

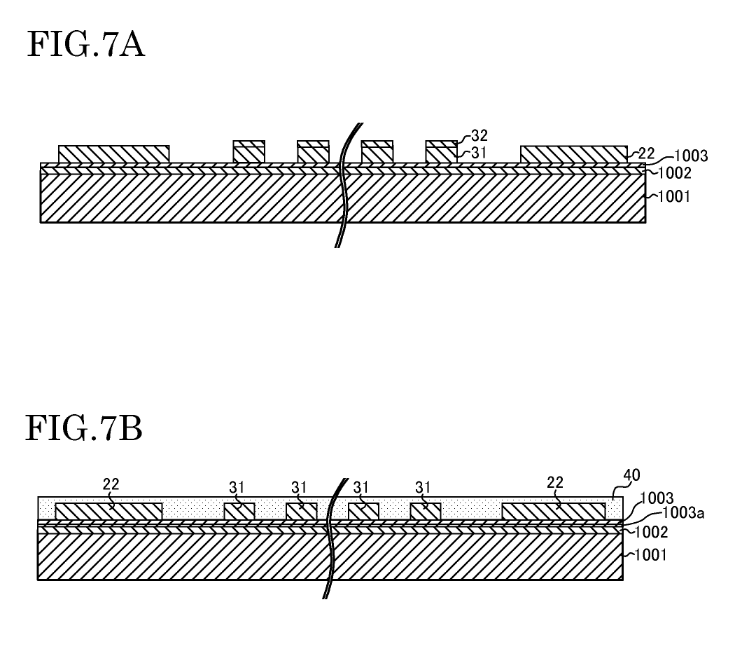

For example, the inventors measured the degree of warping in a wiring board as shown in FIG. 7A, namely, a wiring board without a solder-resist layer, and a wiring board (comparative example) as shown in FIG. 7B, namely, a wiring board with solder-resist layer 40.

The wiring board shown in FIG. 7A is formed by laminating, in the following order, carrier 1001 made of copper with a thickness of 70 μm, copper foil 1002 with a thickness of 5 μm, seed layer 1003 made of nickel with a thickness of 3 μm, and above-described conductive patterns 22 and first pads 31 with a thickness of 18 μm. On each pad 31, above-described second pad 32 with a thickness of 3 μm is formed.

The wiring board shown in FIG. 7B is formed by laminating, in the following order, carrier 1001 made of copper with a thickness of 18 μm, copper foil 1002 with a thickness of 5 μm, seed layer 1003 made of nickel with a thickness of 3 μm, barrier-metal layer (1003a) made of titanium with a thickness of 1 μm, and above-described conductive patterns 22 and first pads 31 with a thickness of 18 μm. In addition, on the second surface of the wiring board, solder-resist layer 40 with a thickness of 20 μm (AUS308 made by Taiyo Ink Co., Ltd. was used) is formed. Solder-resist layer 40 coats conductive patterns 22 and first pads 31.

To find the degree of warping, the distance from the ground level at four spots (regions “P” in FIG. 1) at the corners of each wiring board was measured using a ruler by visual inspection. The unit for measurement was set at 0.5 mm. Such measurement was conducted on three sheets for each wiring board to obtain their respective average values from the measurements of total 12 spots. As a result, the warping degree of the wiring board shown in FIG. 7A was approximately 1.3 mm. On the other hand, the warping degree of the wiring board shown in FIG. 7B was approximately 1.7 mm. Although the measurement was conducted in a stage before mounting electronic component 50, according to simulations by the inventors, it was verified that warping is suppressed by omitting solder-resist layers for electronic-component mounting terminals.

Moreover, change in the degree of warping in each wiring board was observed by placing each board on a hotplate heated at 200° C. In the wiring board shown in FIG. 7A, the degree of warping before heating (room temperature) was approximately 1 mm, the degree of warping during heating (at 200° C.) was approximately 2 mm, and the degree of warping after heating (room temperature) was approximately 0.5 mm. In the wiring board shown in FIG. 7B, the degree of warping before heating (room temperature) was approximately 1.5 mm, the degree of warping during heating (at 200° C.) was approximately 4 mm, and the degree of warping after heating (room temperature) was approximately 2.5 mm. In the wiring board with solder-resist layer 40 as shown in FIG. 7B, the degree of warping after heating was greater than the degree of warping before heating. Judging from that, it is assumed that warping when the electronic component is mounted is caused by a CTE mismatch (difference in coefficients of thermal expansion).

Wiring board 100 is manufactured through the process shown in FIGS. (8A-18C) (each corresponding to FIG. 3), for example.

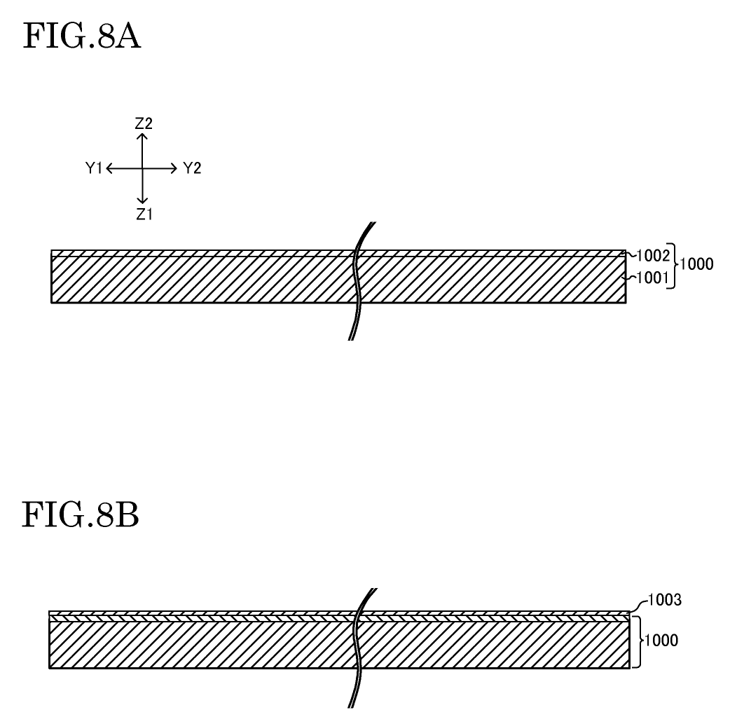

When manufacturing, first support base material 1000 is prepared as shown in FIG. 8A. First support base material 1000 is a copper foil with carrier formed with carrier 1001 made of copper, for example, and copper foil 1002. Carrier 1001 and copper foil 1002 are adhered with an adhesive (removable layer) so that they can be removed (separated) from each other. The thickness of carrier 1001 is 70 μm, for example; and the thickness of copper foil 1002 is 5 μm, for example. The material for carrier 1001 is not limited to copper, but insulative material may also be used.

As shown in FIG. 8B, electroless plating is performed, electrolytic plating or sputtering to form seed layer 1003 made of a metal such as nickel with a thickness of 3 μm, for example. Seed layer 1003 is formed entirely on the surface of copper foil 1002. In doing so, erosion by etching is prevented, and fine patterns may be formed.

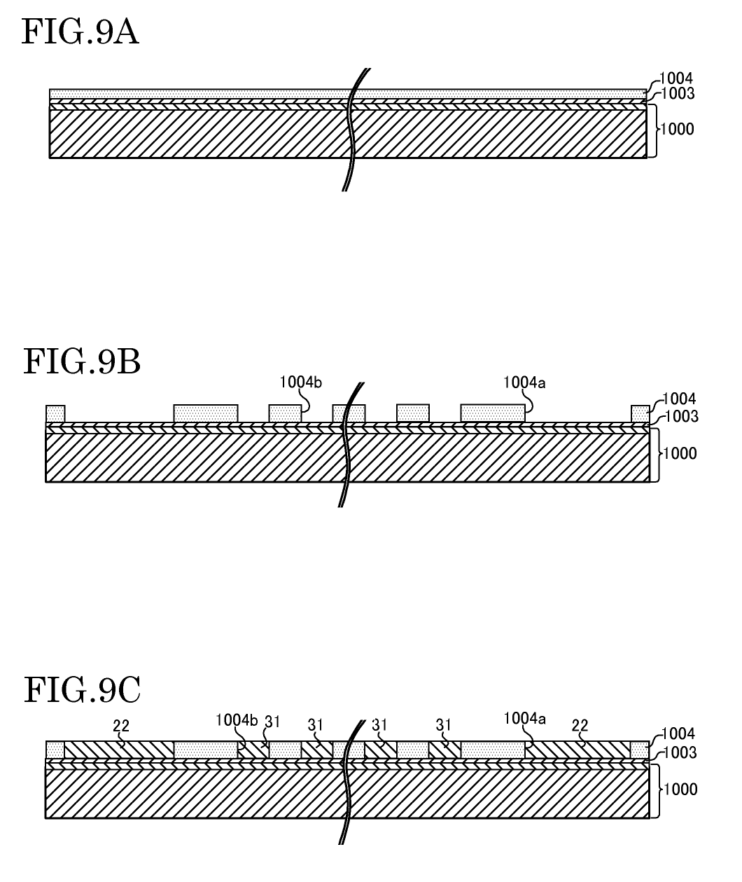

As shown in FIG. 9A, first resist layer 1004 made of dry-film photosensitive resist is laminated on seed layer 1003. From the viewpoint of adhesiveness or etching resistance, first resist layer 1004 is made of material that selectively builds resistance to the material that forms conductive patterns 22 and first pads 31, for example, copper.

First resist layer 1004 is patterned. More specifically, mask film is adhered to first resist layer 1004, which is then exposed to ultraviolet rays and developed with an alkaline solution. By doing so, as shown in FIG. 9B, for example, first opening portions (1004a) and second opening portions (1004b) are formed in areas corresponding to conductive patterns 22 and first pads 31.

The substrate is washed and dried, then electrolytic copper plating is performed. In doing so, as shown in FIG. 9C, for example, conductive patterns 22 and first pads 31 made from copper-plated film with a thickness of 18 μm, for example, are formed respectively in first opening portions (1004a) and second opening portions (1004b). Namely, conductive patterns 22 and first pads 31 are formed on the same surface (the second surface of seed layer 1003). Since conductive patterns 22 and first pads 31 are made from the same material and have the same thickness, both may be formed simultaneously using a single resist layer (first resist layer 1004).

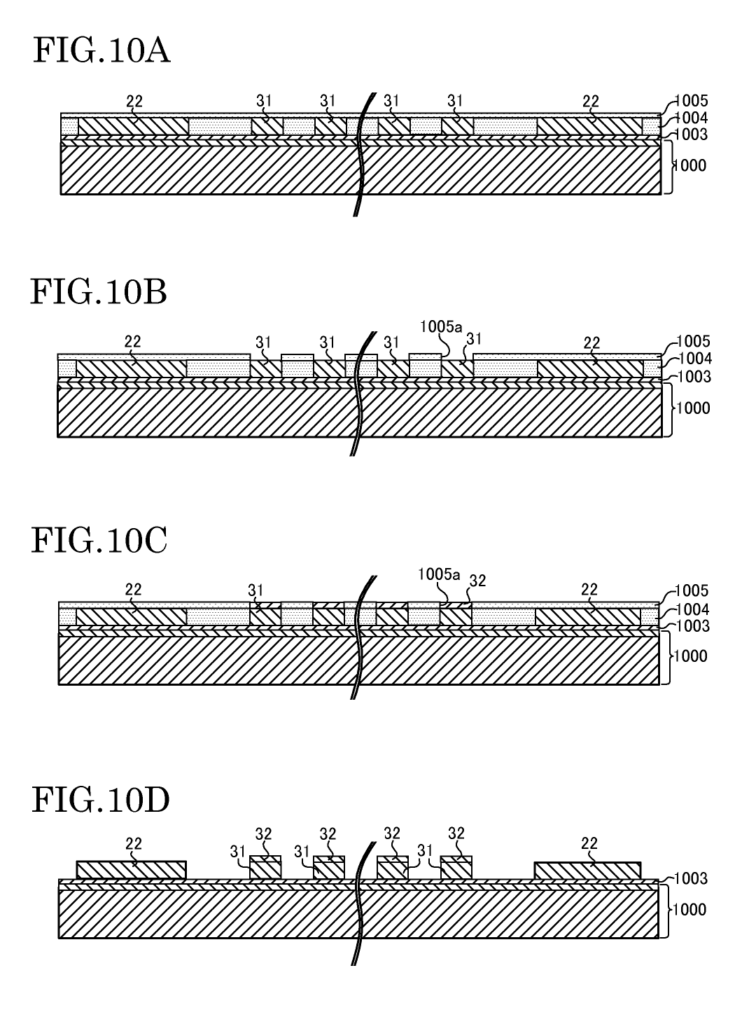

As shown in FIG. 10A, Second resist layer 1005 made of dry-film photosensitive resist, for example is laminated, on first resist layer 1004, conductive patterns 22 and first pads 31. From the viewpoint of adhesiveness or etching resistance, second resist layer 1005 is made of material that selectively builds resistance to the material that forms second pads 32, for example, nickel.

Second resist layer 1005 is patterned. More specifically, mask film is adhered to second resist layer 1005, which is then exposed to ultraviolet rays and developed with a predetermined solution. By doing so, as shown in FIG. 10B, for example, opening portions (1005a) are formed in areas that correspond to second pads 32, and first pads 31 in the central section are exposed. Second resist layer 1005 coats conductive patterns 22, and has openings portions (1005a) positioned on first pads 31.

The substrate is washed and fried, and nickel plating is performed. In doing so, as shown in FIG. 10C, for example, second pads 32 are formed which are made of nickel-plated film with a thickness of 6 μm, for example.

First resist layer 1004 and second resist layer 1005 are removed. In doing so, as shown in FIG. 10D, for example, a substrate is obtained which has conductive patterns 22, first pads 31 and second pads 32 formed on its second surface.

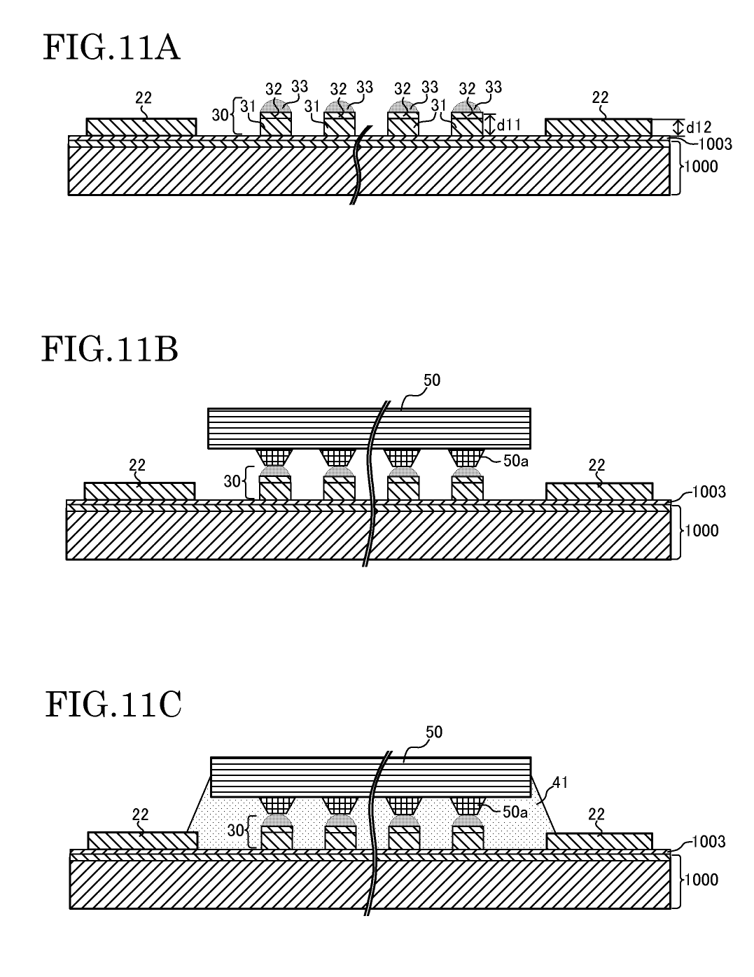

Flux is applied to the entire surface of the substrate and, for example, electrolytic plating is performed to form solder paste on second pads 32. Then, by reflowing the solder paste in a nitride atmosphere, for example, bonding layers 33 made of solder-plated film with a thickness of 14 μm, for example, are formed on second pads 32, as shown in FIG. 11A. During that time, since second pad 32 is formed on first pad 31, the total height of first pad 31 and second pad 32, namely, height (d11) of the pad, is greater than height (d12) of conductive pattern 22. Accordingly, bonding layer 33 tends to adhere to each second pad 32, rather than adhering to conductive pattern 22. Moreover, since height (d11) of a pad is 5 μm or greater than height (d12) of conductive pattern 22, sufficient adhesion results may be expected. In addition, second pad 32 has a higher level of wettability with the material of bonding layer 33 (for example, solder) than first pads 31 or conductive pattern 22. Thus, bonding layer 33 tends to adhere to each second pad 32. Therefore, according to a manufacturing method of the present embodiment, even if conductive pattern 22 is not coated with a protective material related to bonding layer 33, bonding layer 33 will not adhere to conductive pattern 22 and may be formed selectively on second pad 32. Then, by reflowing connection terminal 30, bonding layer 33 forms on each second pad 32 without flowing over to adjacent connection terminal 30. Accordingly, such bonding layers 33 may be formed with a uniform height.

According to the manufacturing method of the present embodiment, bonding layers 33 are formed by plating, not by solder agglomeration. Thus, barrier layer (1003a) (FIG. 7B) or the like may be omitted.

By a step shown in FIG. 11A, bonding layer 33 is formed on each second pad 32. Accordingly, connection terminals 30 are formed to electrically connect conductive patterns (wiring layers 14, 15, etc.) of wiring board 100 and bumps (50a) of electronic component 50.

Electronic component 50 is mounted facedown onto the second surface of the substrate as shown in FIG. 11B, for example. Then, bumps (50a) of electronic component 50 are bonded to connection terminals 30. In doing so, electronic component 50 is mounted on the second surface of the substrate.

After mounting electronic component 50, t underfill 41 made of insulative resin containing inorganic filler such as silica or alumina is filled into the gaps between electronic component 50 and the substrate, as shown in FIG. 11C, for example.

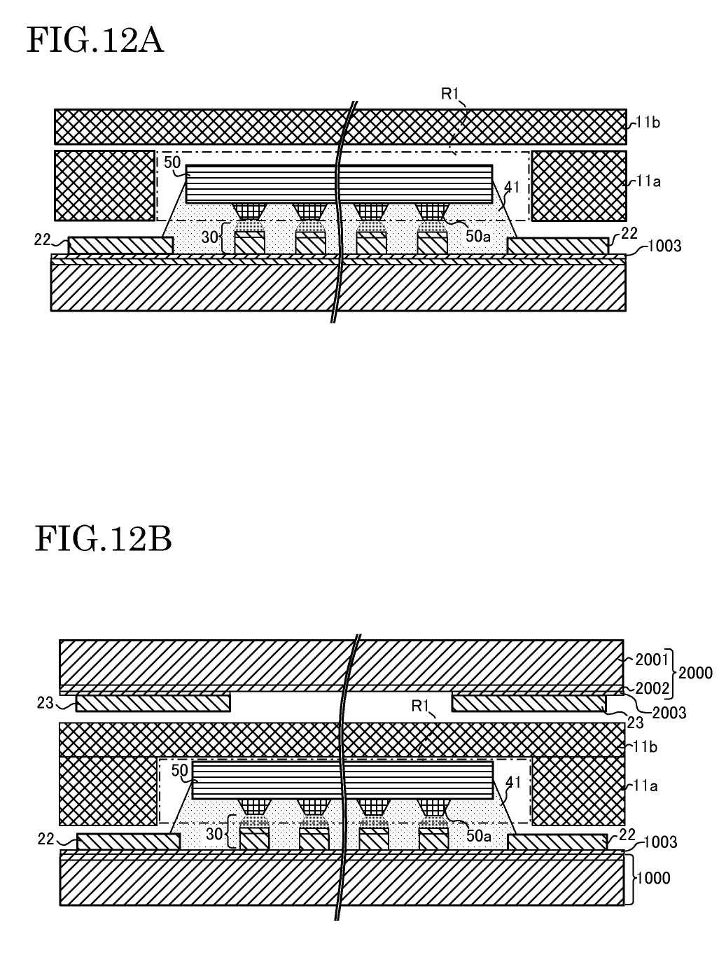

Insulative material (11a), which has space (R1) corresponding to the external shape of electronic component 50, and board-type insulative material (11b) are mounted in that order on the second surface of the substrate, as shown in FIG. 12A, for example. During that time, electronic component 50 is arranged in space (R1). Insulative materials (11a, 11b) are both made from prepreg. Such prepreg contains reinforcing material such as glass fiber or aramid fiber, which is then impregnated with resin. Space (R1) is formed by, for example, punching, mechanical drilling or laser processing.

Second support base material 2000 is prepared, as shown in FIG. 12B, for example. Second support base material 2000 is formed by laminating carrier 2001 with an approximate thickness of 70 μm and copper foil 2002 with an approximate thickness of 5 μm. On copper foil 2002, seed layer 2003 made of, for example, nickel with an approximate thickness of 3 μm and conductive patterns 23 made of, for example, copper-plated film with an approximate thickness of 18 μm are laminated in that order. Basically, they may be manufactured by substantially the same method as the method used when manufacturing first support base material 1000, seed layer 1003 and conductive patterns 22.

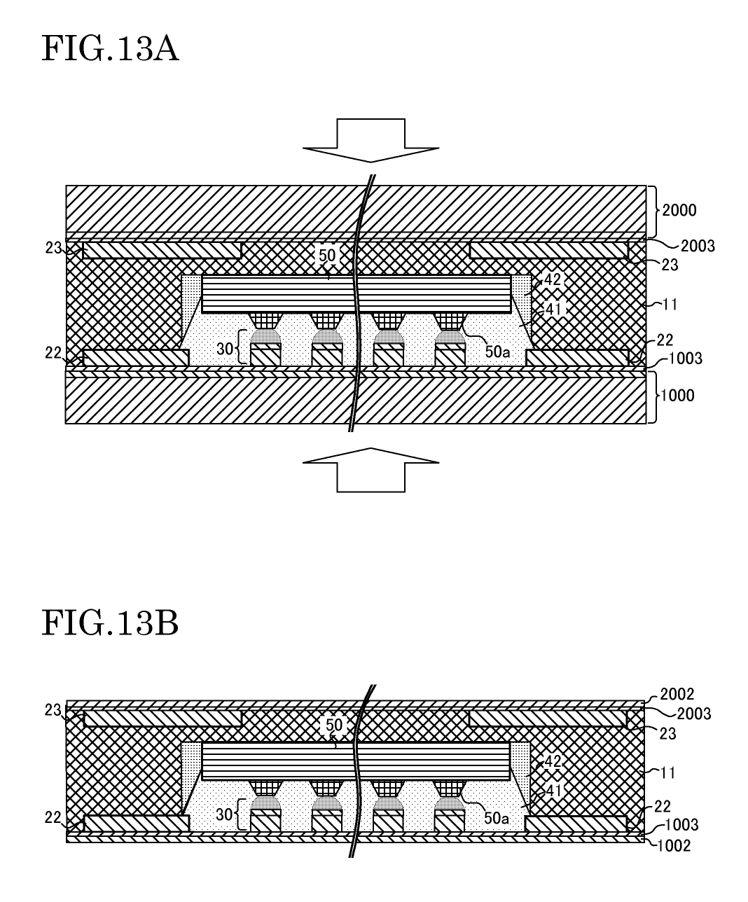

Second support base material 2000 is mounted on the substrate in such a way that the first surface (the side where conductive patterns 23 are formed) of second support base material 2000 makes contact with the second surface of insulative material (11b). Then, the substrate is pressurized from both the arrow-Z1 side and the arrow-Z2 side (see FIG. 8A for definition of arrows) using lamination methods such as autoclave methods or hydraulic pressing methods. In doing so, insulative material (11a) and insulative material (11b) are fused and insulation layer 11 is formed as shown in FIG. 13A, for example. Also, during such pressurization, resin ingredients drain from insulation layer 11. Such resin ingredients are filled as filler 42 between electronic component 50 and insulation layer 11.

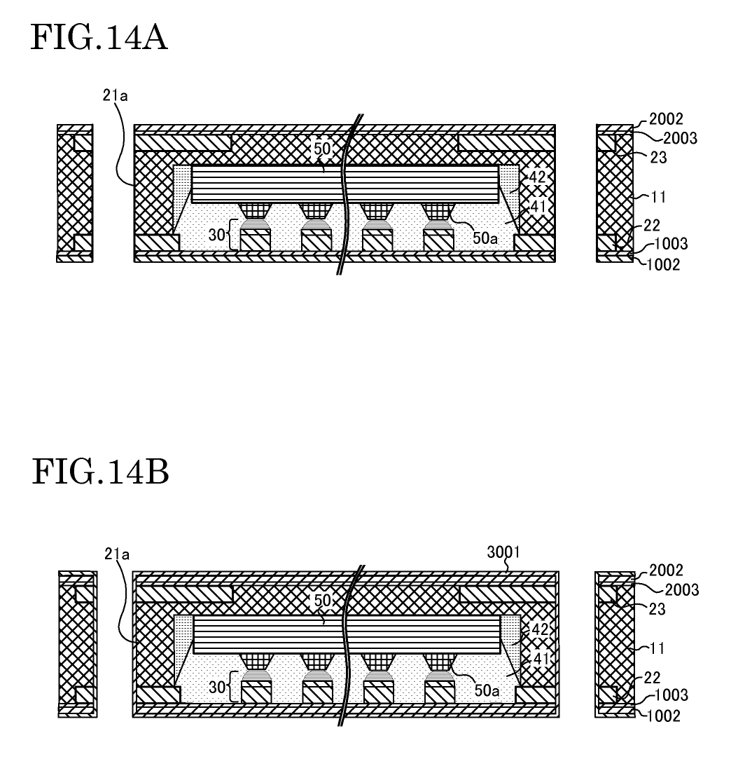

Carrier 1001 and carrier 2001 are removed (separated) from the substrate. After that, by known drilling methods using a mechanical drill or the like, through-holes (21a) are formed to penetrate the substrate, as shown in FIG. 14A, for example. Next, electroless copper plating is performed on the substrate to form copper-plated layers 3001 on both surfaces of the substrate and the inner walls of through-holes (21a) as shown in FIG. 14B, for example.

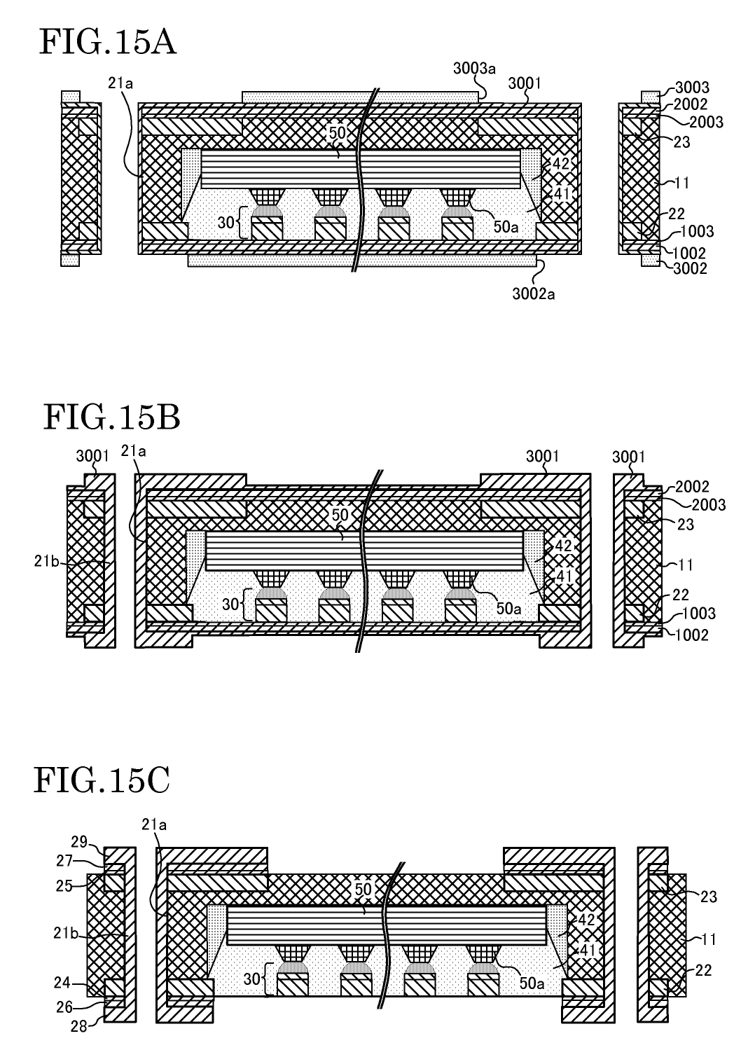

Resist layers (3002, 3003) made of dry-film photosensitive resist is laminated on both surfaces of the substrate, and resist layers (3002, 3003) are patterned. More specifically, mask film is adhered to resist layers (3002, 3003), which are then exposed to light and developed. In doing so, resist layers (3002, 3003) are formed with their respective opening portions (3002a, 3003a) in areas corresponding to conductive patterns (28, 29), as shown in FIG. 15A, for example.

The substrate is washed and dried, and electrolytic copper plating is performed. Resist layers (3002, 3003) are removed. Accordingly, areas of copper-plated layer 3001 which correspond to conductive patterns (28, 29) and through-hole conductors (21b) become thicker, as shown in FIG. 15B, for example. As a result, through-hole conductors (21b) are formed on the inner walls of through-holes (21a).

Unnecessary copper is removed from both surfaces of the substrate, namely, the unnecessary portions of copper-plated layer 3001, by etching, for example. In the following, unnecessary portions of copper foils (1002, 2002) and seed layers (1003, 2003) are removed by etching, for example. Accordingly, first base layers (24, 25), second base layers (26, 27) and conductive patterns (28, 29) are formed, as shown in FIG. 15C. At that time, etching each metal is conducted using an etchant which selectively etches the intended metal. In doing so, when etching first base layer 24 and second base layer 26, or first base layer 25 and second base layer 27, their respective upper-layer conductive patterns 28 or 29 will be seldom etched. As a result, fine conductive patterns (28, 29) may be formed.

The substrate shown in FIG. 15C may be used as a substrate with a built-in electronic component. However, in the present embodiment, the lamination process is further conducted to make a multilayer wiring board.

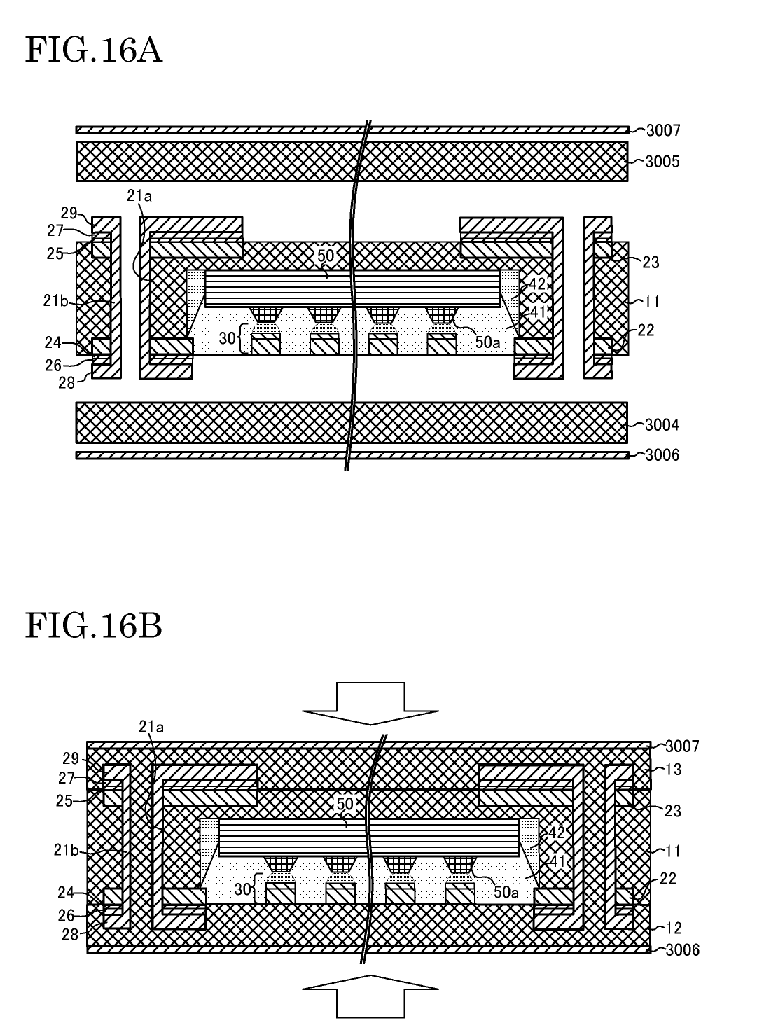

Insulation layers (3004, 3005), which are made of board-type prepreg or the like containing reinforcing material, and copper foils (3006, 3007) are arranged on both surfaces (first and second surfaces) of the substrate, as shown in FIG. 16A, for example. Prepreg for insulation layers (3004, 3005) contains reinforcing material such as glass fiber or aramid fiber, which is then impregnated with resin. As for copper foils (3006, 3007), for example, rolled copper foil or electrolytic copper-plated foil may be used.

The substrate is thermopressed as shown in FIG. 16B. In doing so, insulation layers (3004, 3005) become insulation layers (12, 13) respectively. During that time, the amount of resin squeezed from first base layers (24, 25), second base layers (26, 27) and conductive patterns (28, 29) will be offset by the amount of resin seeping into the interiors (gaps) of through-holes (21a). Therefore, the surfaces of insulation layers (3004, 3005) remain flat.

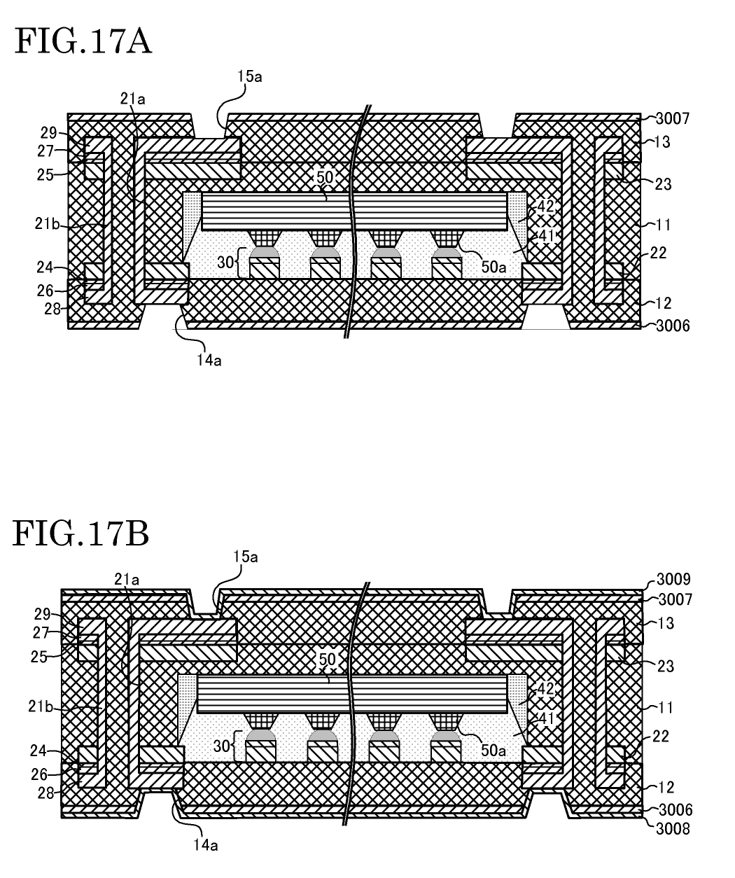

Penetrating holes (14a, 15a) (blind holes) that penetrate insulation layers (12, 13) are formed on predetermined spots of both surfaces of the substrate using carbon dioxide (CO₂) laser, UV-YAG laser or the like, as shown in FIG. 17A, for example.

Electroless copper plating is performed entirely on the surfaces of the substrate to form copper-plated layers (3008, 3009) on both surfaces including the inner surfaces of penetrating holes (14a, 15a), as shown in FIG. 17B, for example.

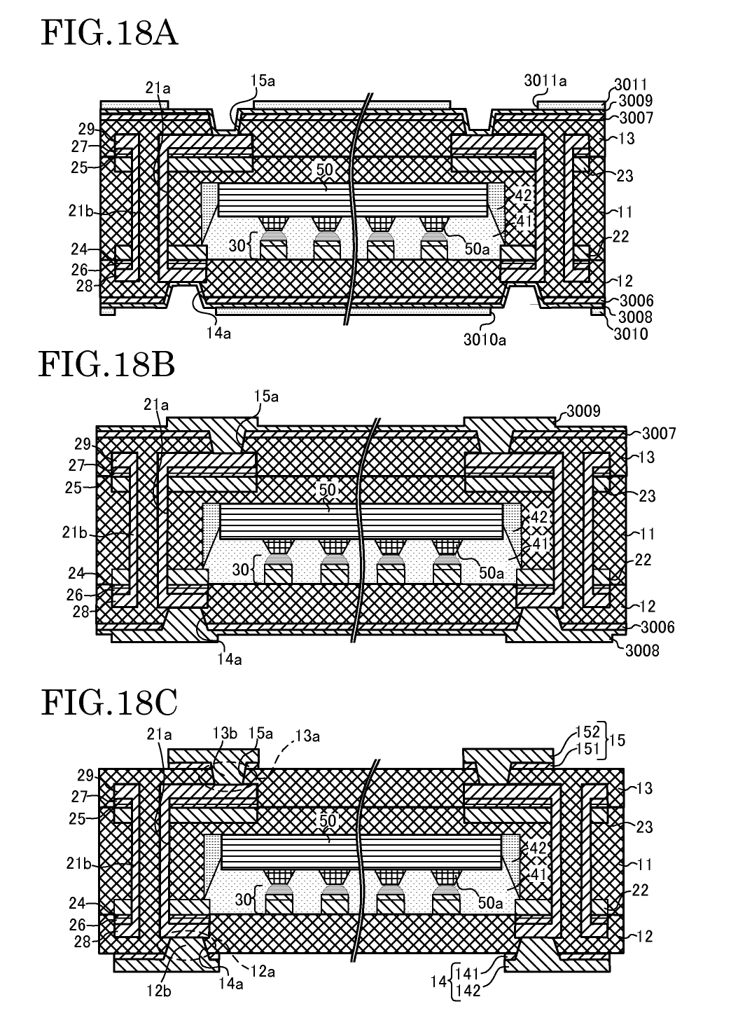

Resist layers (3010, 3011) made of dry-film photosensitive resist are laminated on both surfaces of the substrate, and patterns resist layers (3010, 3011). More specifically, a mask film is adhered to resist layers (3010, 3011), which are then exposed to light and developed. In doing so, resist layers (3010, 3011) are formed with their respective opening portions (3010a, 3011a) in areas corresponding to wiring layers (14, 15), as shown in FIG. 18A, for example.

The substrate is washed and dried and electrolytic copper plating is performed. Resist layers (3010, 3011) are removed. Accordingly, areas of copper-plated layers (3008, 3009) which correspond to wiring layers (14, 15) become thicker, as shown in FIG. 18B, for example.

Unnecessary copper is etched away from both surfaces of the substrate, namely, unnecessary portions of copper-plated layers (3008, 3009). In doing so, as shown in FIG. 18C, for example, wiring layer 14 formed with first wiring layer 141 and second wiring layer 142 is formed on the first surface of insulation layer 12; and wiring layer 15 formed with first wiring layer 151 and second wiring layer 152 is formed on the second surface of insulation layer 13. Wiring layers (14, 15) are electrically connected to conductive patterns (28, 29) by means of conductors (12b, 13b) of penetrating holes (14a, 15a). Namely, parts of penetrating holes (14a, 15a) function as via holes (12a, 13a) (specifically, filled vias) to be used for interlayer connection.

Solder-resist layers (16, 17) (see FIG. 3) are formed with predetermined patterns by screen printing, spray coating, roll coating or the like, for example. Opening portions (16a) are formed in solder-resist layer 16; and opening portions (17a) are formed in solder-resist layer 17. Wiring layers (14, 15) are exposed through their respective opening portions (16a, 17a).

Wiring board 100 is obtained as shown previously in FIG. 1 through the above processes. After that, for example, by forming solder bumps or the like in opening portions (16a, 17a) in the outermost layers, such portions become external connection terminals. External connection terminals are used for electrical connections with other wiring boards, electronic components or the like.

According to the manufacturing method of the present embodiment, when forming terminals for mounting electronic components, namely, connection terminals 30, protective material (such as solder resist or the like) related to bonding layers 33 is not required. Thus, warping caused by temperature changes during the manufacturing process or a heat cycle afterward may be suppressed from occurring in the substrate. Also, bonding layers 33 with a uniform height are formed on second pads 32. Accordingly, in wiring board 100, high connection reliability is achieved in areas for mounting electronic component 50 and so forth.

Moreover, each connection terminal 30 may be formed without short-circuiting adjacent connection terminals 30. Accordingly, wiring board 100 may be manufactured, which can deal with highly integrated wiring of electronic component 50 and subsequent fine-pitch wiring.

In the manufacturing method of the present embodiment, connection terminals 30 are formed by a two-step resist method, using first resist layer 1004 and second resist layer 1005. By doing so, connection terminals 30, which are taller than conductive patterns 22, may be formed appropriately.

So far, a wiring board and its manufacturing method according to an embodiment of the present invention have been described. However, the present invention is not limited to such. For example, the present invention may be carried out by the following modifications.

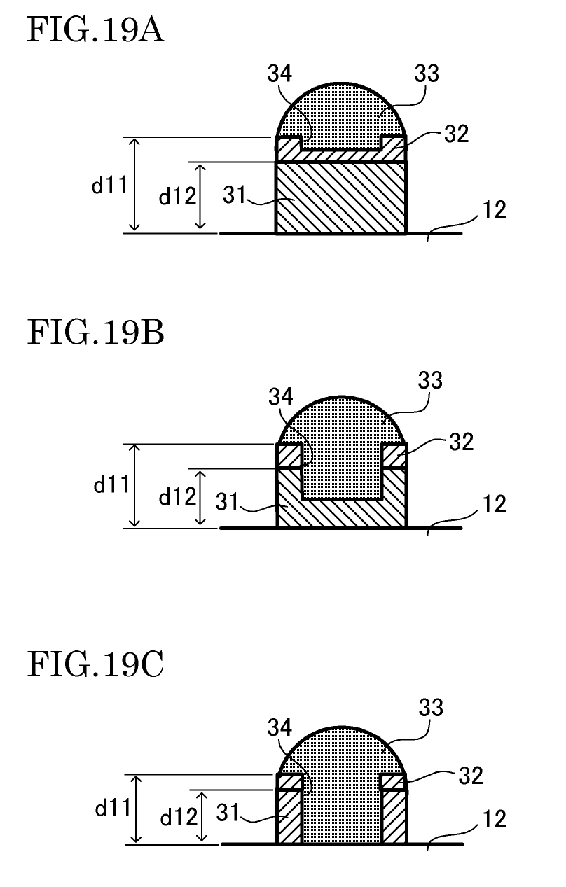

To further enhance agglomeration of bonding layer 33, cavity 34 may be formed at the tip of a pad, namely in pad 32, as shown in FIG. 19A, for example. Alternatively, as shown in FIG. 19B or 19C, cavity 34 may be formed so as to reach first pad 31 or insulation layer 12.

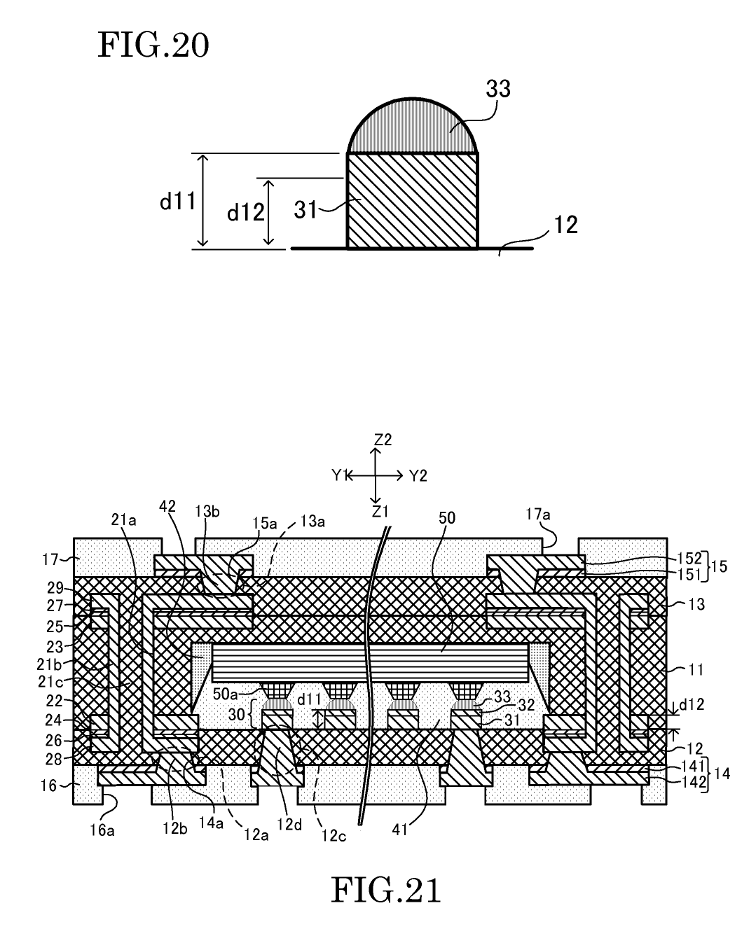

The above embodiment used a pad made up of first pad 31 and second pad 32, which are formed using different materials from each other. However, the present invention is not limited to such; pads for mounting electronic component 50 may be formed with a single material. For example, as shown in FIG. 20, a pad may be formed only with first pad 31 by omitting second pad 32. In such a case, connection terminals 30 may be formed appropriately using a two-step resist method. Also, by making the height of first pad 31, namely height (d11) of the pad, greater than height (d12) of conductive pattern 22, agglomeration of bonding layer 33 may be enhanced.

Via holes (12c) connected to connection terminals 30 may be formed as shown in FIG. 21, for example. Then, connection terminals 30 and their upper-layer wiring or external devices may be electrically connected by means of via holes (12c). Such a structure is effective when terminals are set in an area array. Also, in the example shown in FIG. 21, filled vias in which conductors (12d) are filled in via holes (12c) are used. However, instead of filled vias, for example, conformal vias may also be used.

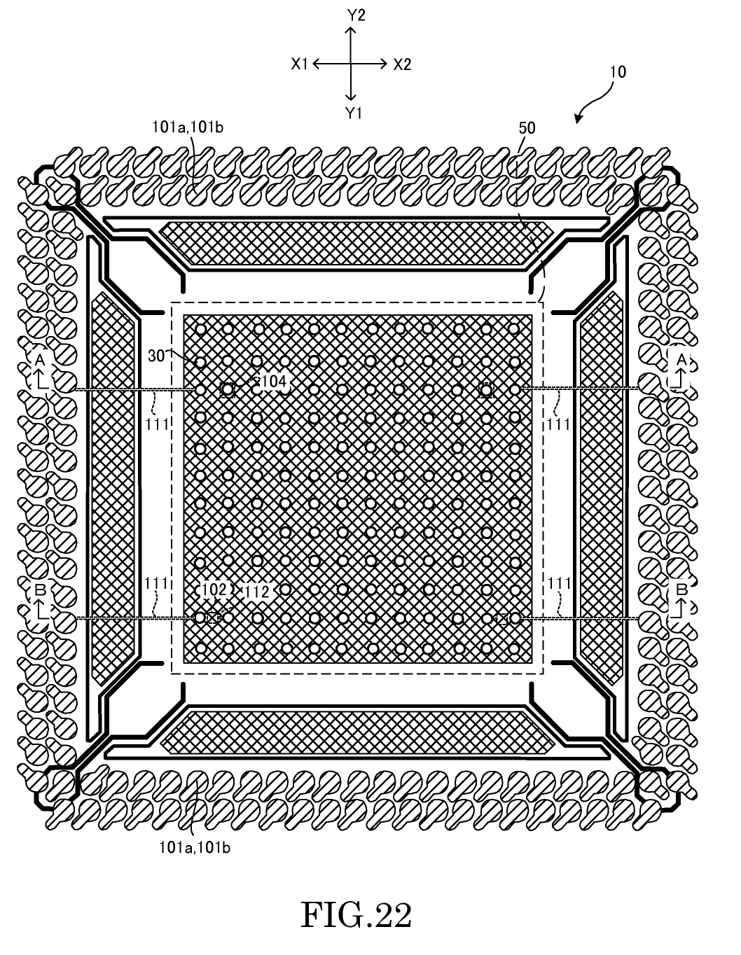

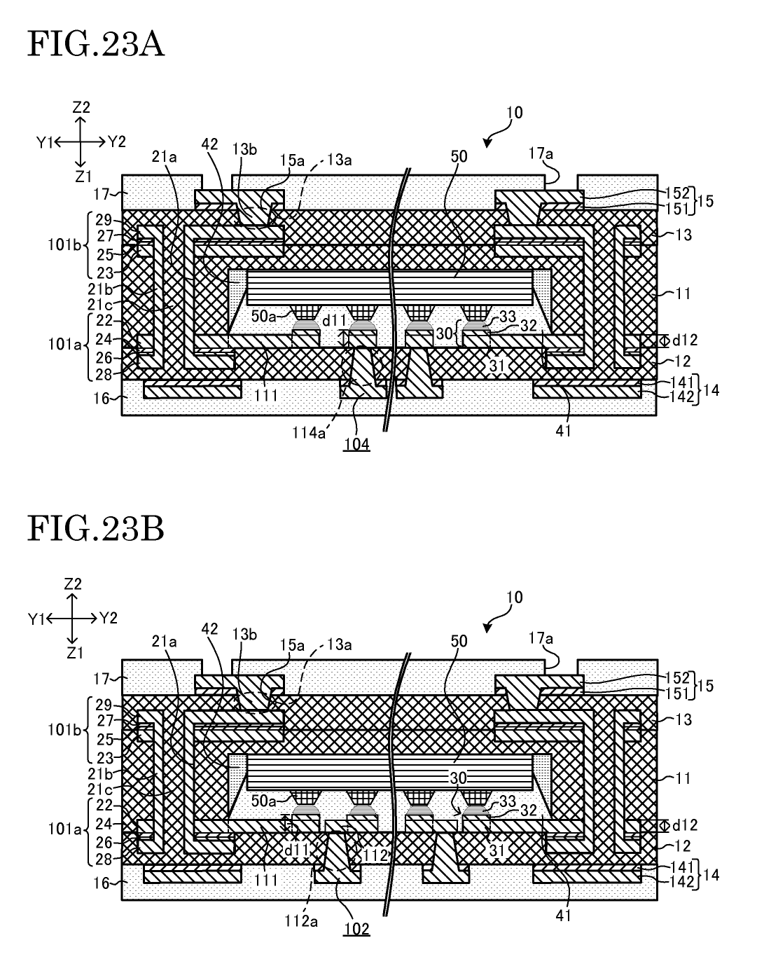

The arrangement of connection terminals 30 is not limited to a peripheral array; any other arrangement may be used. For example, FIG. 22 shows a method for connecting connection terminals 30. Connection terminals 30 may be arranged in a grid array (for example, a full grid array) as shown in FIG. 22, for example. In the example shown in FIG. 22, predetermined connection terminal 30 is electrically connected to through-hole lands (101a, 101b) on both surfaces of wiring board 100 by means of lead wire 111. Another predetermined connection terminal 30 is electrically connected to pad 104 directly on its top (the arrow-Z1 direction) by means of filled via (114a) as shown in FIG. 23A (cross-sectional view taken from the A-A line of FIG. 22). Yet another predetermined connection terminal 30 is distributed toward the outside by means of lead wire 112 as shown in FIG. 23B (cross-sectional view taken from the B-B line of FIG. 22). Lead wire 112 is electrically connected to upper-layer pad 102 by means of filled via (112a). Connecting connection terminals 30 is not limited to the above method, and any other method may also be employed. For example, connection terminals 30 may be connected only to lands, external terminals, inner terminals or terminals directly on their top (pads 104), or to any combination of those. Also, any type of interlayer connection may be employed: namely, instead of filled vias (112a) or (114a), conformal vias may be used.

Electrical connection between both surfaces (first surface and second surface) of wiring board 100 is not limited to connection by through-hole conductors (21b), and any other type may be used.

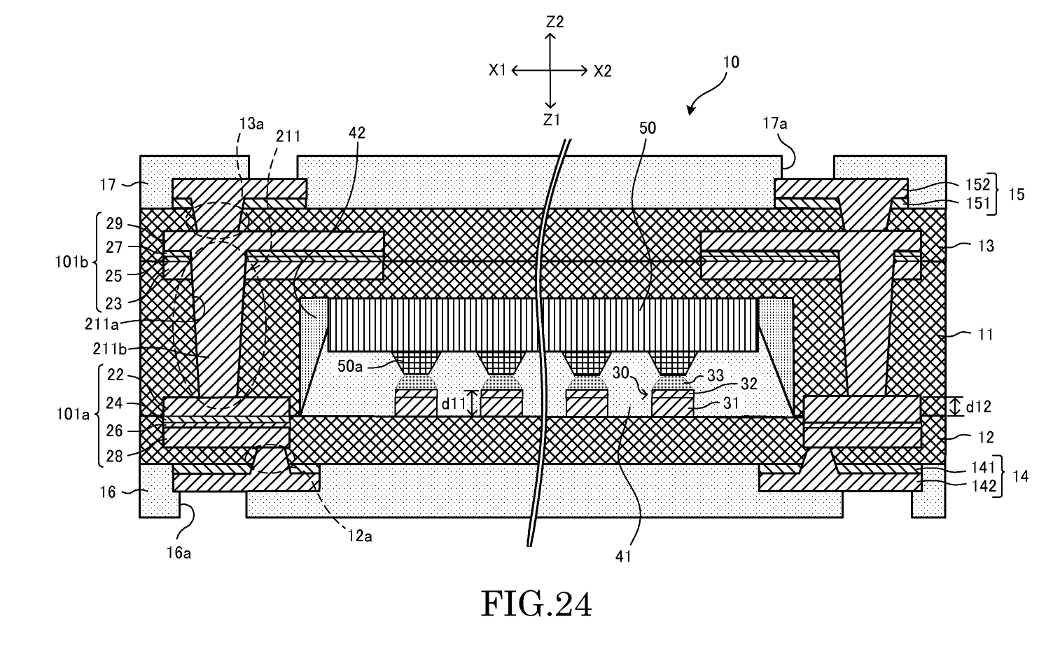

As shown in FIG. 24, for example, through-hole land (101a) and through-hole land (101b) may be connected by means of filled via 211. Filled via 211 is made up of tapered via hole (211a) and conductor (211b). Conductor (211b) is filled in via hole (211a). Conductor (211b) is contiguous to conductive pattern 29 and connected to the second surface of conductive pattern 22.

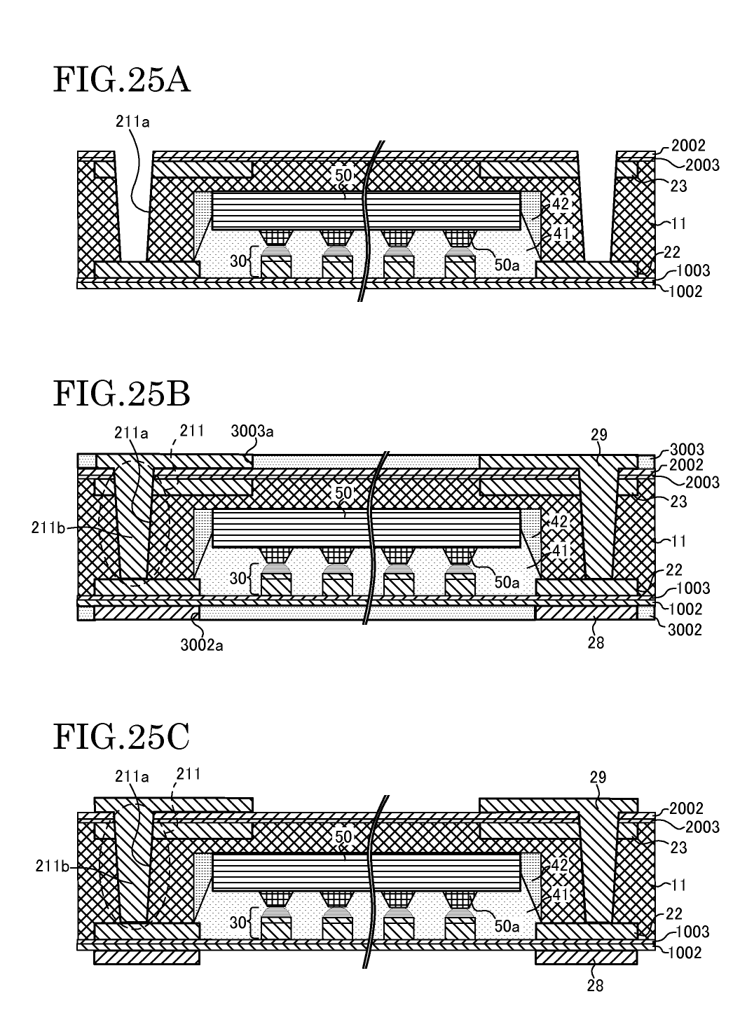

Filled via 211 may be formed by the steps shown in FIGS. 25A-25C instead of the steps shown in FIGS. 14A-15B, for example. In such a case, tapered via hole (211a) is formed on the second surface of the substrate to be connected to conductive pattern 22 by a carbon dioxide gas (CO₂) laser, UV-YAG laser or the like, as shown in FIG. 25A, for example. Resist layers (3002, 3003) having opening portions (3002a, 3003a) are formed on both surfaces of the substrate. As shown in FIG. 25B, for example, conductor (211b) is filled in via hole (211a), while conductive patterns (28, 29) are formed in areas corresponding to opening portions (3002a, 3003a). Accordingly, filled via 211 is formed. Resist layers (3002, 3003) are removed, as shown in FIG. 25C.

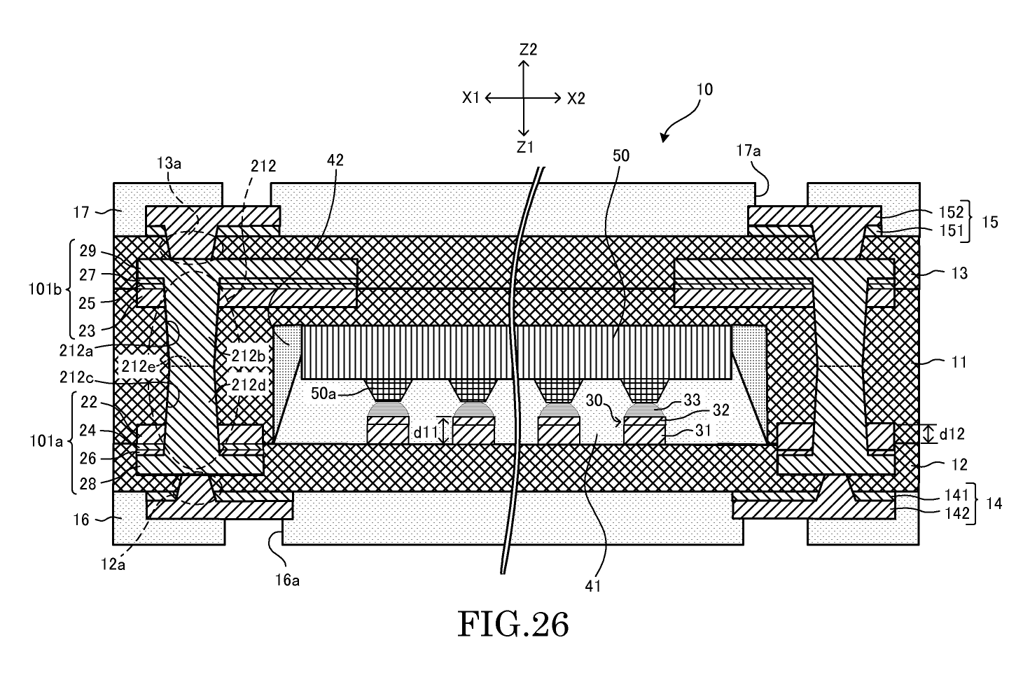

Alternatively, as shown in FIG. 26, for example, through-hole land (101a) and through-hole land (101b) may be connected by means of filled through-hole 212 configured like an hourglass (shaped like a traditional Japanese hand drum). Filled through-hole 212 is made up of tapered holes (212a, 212c) and conductors (212b, 212d). The diameters of holes (212a, 212c) decrease toward the lower layer (core). Holes (212a, 212c) are joined at surface (212e) of filled through-hole 212 where the diameter becomes smallest. Holes (212a, 212c) are configured to be symmetrical, for example. In hole (212a), conductor (212b) made of copper-plated film, for example, is filled; and in hole (212c), conductor (212d) made of copper-plated film, for example, is filled. By employing such hourglass-shaped filled through-hole 212 made of filled plated film, the rigidity of the wiring board is enhanced and warping may be suppressed. Also, since via holes may be stacked directly on filled through-hole 212, sufficient wiring space is secured to achieve highly integrated wiring. Furthermore, the diameter of the entrance for plating solutions is set relatively large, while the diameter of portions where plating solutions are hard to seep into is set relatively small. Accordingly, plating solutions may be completely filled.

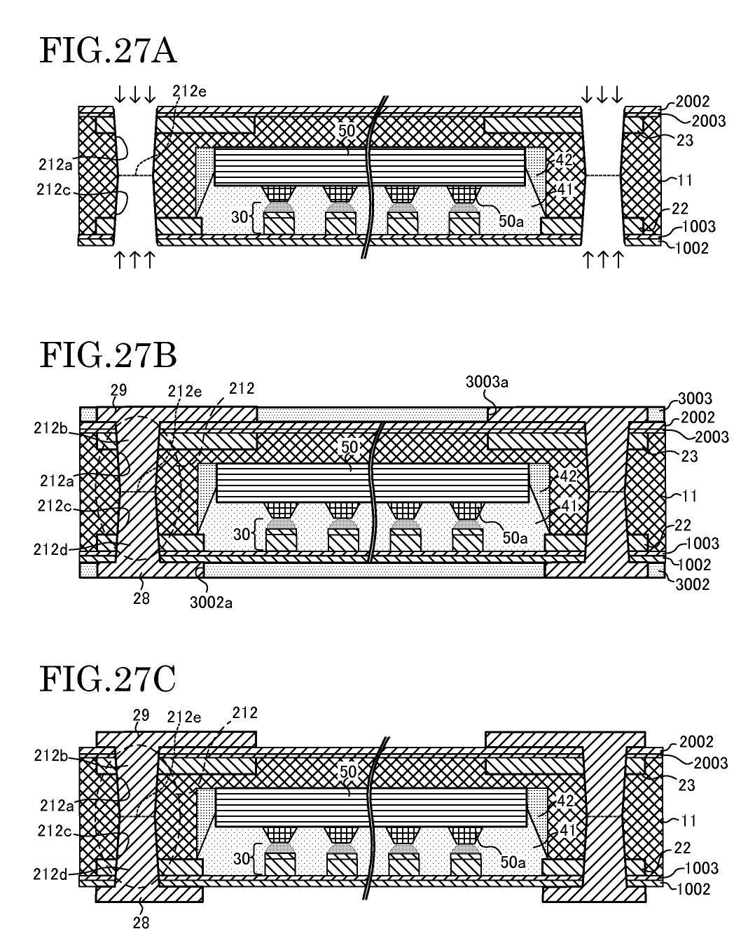

Filled through-holes 212 may be formed by the steps shown in FIGS. 27A-27C instead of the steps shown in FIGS. 14A-15B, for example. In such a case, tapered holes (212a, 212c) are formed at the predetermined spots of both surfaces (first and second surfaces) of the substrate by a carbon dioxide gas (CO₂) laser, UV-YAG laser or the like, as shown in FIG. 27A, for example. Holes (212a, 212c) are joined at their middle surface (212e), where the diameter becomes the smallest, and are configured like an hourglass. Resist layers (3002, 3003) having opening portions (3002a, 3003a) are formed on both surfaces of the substrate. As shown in FIG. 27B, for example, conductors (212b, 212d) are filled in holes (212a, 212c) respectively, while conductive patterns (28, 29) are formed in areas corresponding to opening portions (3002a, 3003a). Accordingly, conductors (212b, 212d) are joined at their middle surface (212e), where the diameter becomes the smallest, and are configured like an hourglass. Accordingly, hourglass-shaped filled through-hole 212 is formed. Resist layers (3002, 3003) are removed, as shown in FIG. 27C.

By forming holes from each of the first surface and second surface, a filled through-hole other than hourglass-shaped through-hole 212 may be obtained. Such a through-hole other than hourglass-shaped through-hole 212 may be employed if required. Alternatively, a filled hole formed by joining holes with asymmetrical shapes may be used. For example, a tapered hole and a cylindrical hole having the same diameter as the tapered hole may be joined to form a filled through-hole.

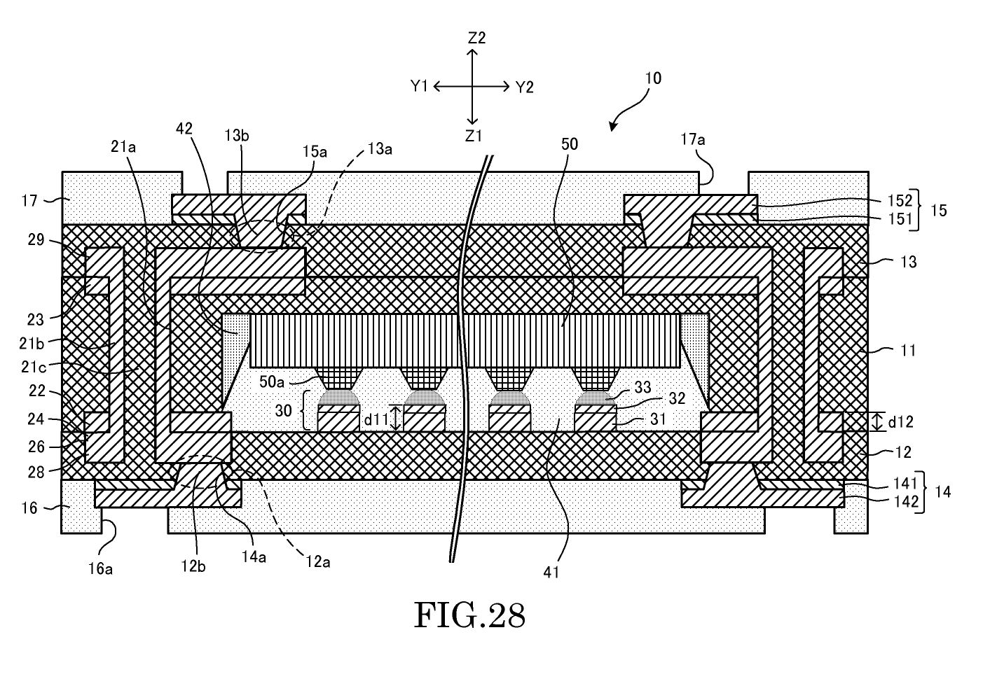

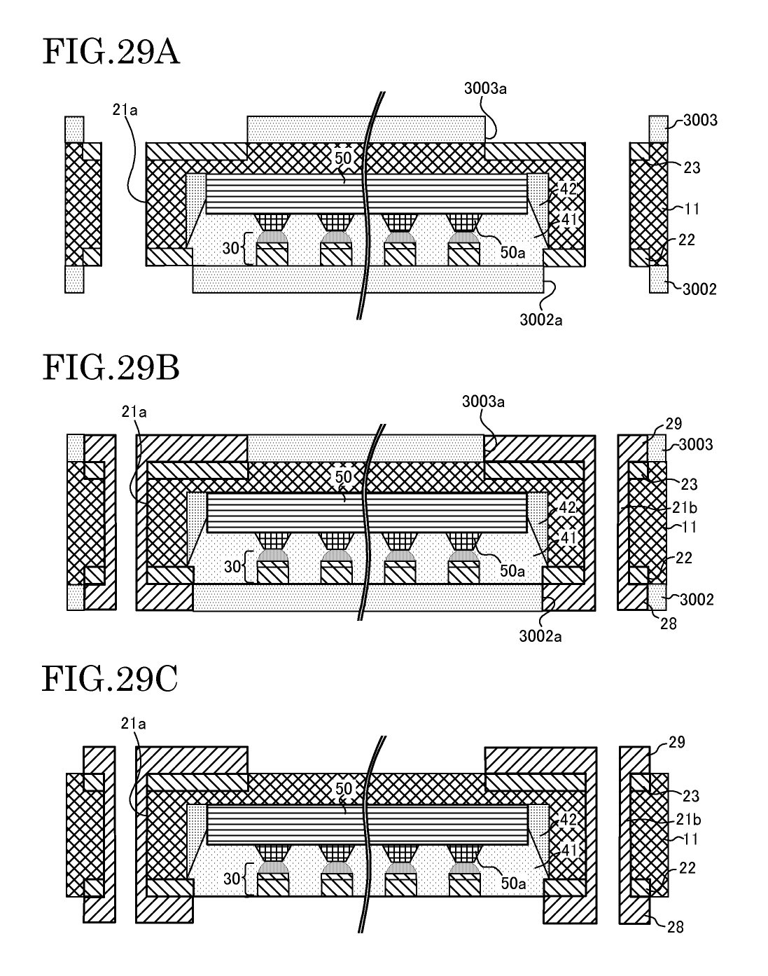

In wiring board 100 of the above embodiment, as shown in FIG. 28, first base layers (24, 25) and second base layers (26, 27) may be omitted unless necessary. In such a case, instead of the steps shown in FIGS. (15A-15C), steps shown in FIGS. (29A-29C) are conducted. Namely, on the substrate where first base layers (24, 25) and second base layers (26, 27) are not formed, the following are conducted: forming through-holes (21a) and resist layers (3002, 3003) (see FIG. 29A); forming conductive patterns (28, 29) and through-hole conductors (21b) (see FIG. 29B); removing resist layers (3002, 3003) (see FIG. 29C); and subsequent steps.

In the above embodiment, the material, size and number of layers of each layer may be modified. For example, the structure shown in FIG. 3 and FIGS. (4A-4C) is completed, the lamination process may further be continued to make an even multilayer (for example, six-layer or eight-layer) wiring board. Also, the number of layers on each surface (first surface and second surface) of wiring board 100 may be different. Furthermore, layers (wiring layers and insulation layers) may be formed (laminated) only on one side of the wiring board (more specifically, on one surface of the core substrate).

The order of the steps in the above embodiments may be changed within a scope that will not deviate from the gist of the present invention. Also, one or more steps may be omitted according to usage requirements or the like.

Bonding layers 33 may be formed by a method other than plating according to usage requirements or the like.

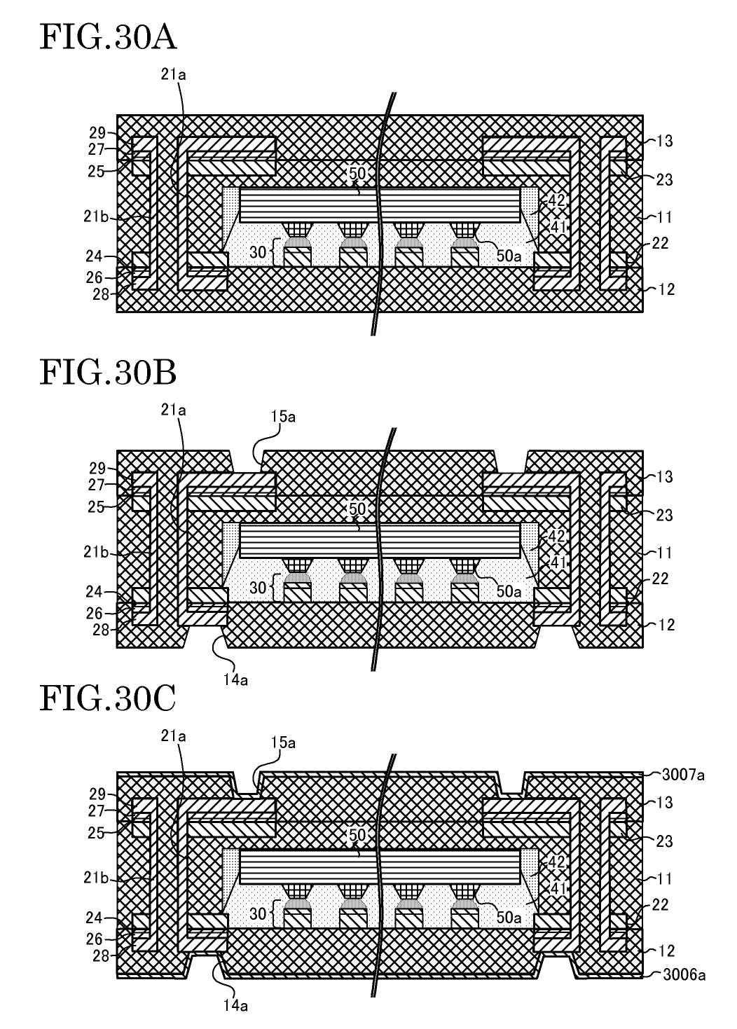

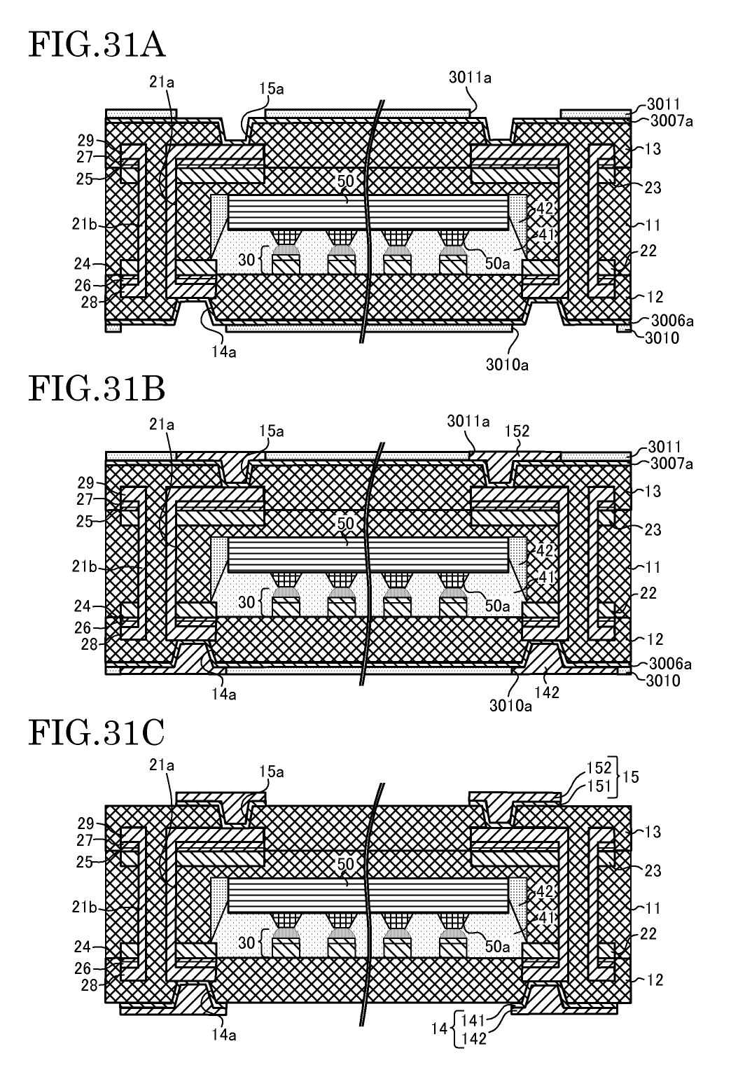

Wiring layers (14, 15) may also be formed by a semi-additive method (SAP). More specifically, the steps shown in FIGS. 8A-16B are carried out to form insulation layers (12, 13) as shown, for example, in FIG. 30A. As shown in FIG. 30B, for example, penetrating holes (14a, 15a) (blind holes) are formed to penetrate insulation layers (12, 13) at predetermined spots of both surfaces of the substrate using carbon dioxide gas (CO₂) laser, UV-YAG laser or the like. As shown in FIG. 30C, for example, electroless copper plating is performed on the entire surface of the substrate, and copper-plated layers (3006a, 3007a) are formed on both surfaces including the inner surfaces of penetrating holes (14a, 15a). As shown in FIG. 31A, for example, resist layers (3010, 3011) having opening portions (3010a, 3011a) are formed on both surfaces of the substrate. As shown in FIG. 31B, for example, second wiring layers (142, 152) made of electrolytic copper-plated film are formed in areas corresponding to opening portions (3010a, 3011a). After removing resist layers (3010, 3011), unnecessary portions of copper on both surfaces of the substrate are removed by etching, for example. In doing so, as shown in FIG. 31C, for example, wiring layer 14 formed with first wiring layer 141 and second wiring layer 142 is formed on the first surface of insulation layer 12; and wiring layer 15 formed with first wiring layer 151 and second wiring layer 152 is formed on the second surface of insulation layer 13.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board comprising:
a substrate;
a first conductive pattern formed on a surface of or inside the substrate;
a plurality of pads with a predetermined pitch formed on the same layer as the first conductive pattern;
conductive bonding layers arranged on each of the plurality of pads; and
an electronic component having electrodes,
wherein the electronic component is arranged inside the substrate, the electrodes of the electronic component and the plurality of pads are electrically connected by means of the bonding layers, the height of each of the plurality of pads is greater than the height of the first conductive pattern adjacent to the pad, and a protective material related to the bonding layers is not formed at least on the layer where the plurality of pads and the first conductive pattern are formed.

2. The wiring board according to claim 1, wherein the height of each of the plurality of pads is 5 μm or greater than the height of the first conductive pattern.

3. The wiring board according to claim 1, wherein each of the plurality of pads contains a first pad and a second pad which are made of a material different from each other.

4. The wiring board according to claim 3, wherein the bonding layers are formed on the second pads, and the second pads have higher wettability with the material of the bonding layers than the first pads.

5. The wiring board according to claim 4, wherein the first pads are made of copper and the second pads are made of nickel.

6. The wiring board according to claim 3, wherein the first pads and the first conductive pattern are arranged on the same layer, and the first pads and the first conductive pattern are made with the same material and have the same thickness.

7. The wiring board according to claim 1, wherein the plurality of pads are made of a single material.

8. The wiring board according to claim 1, wherein the bonding layers are made of solder, and the protective material related to the bonding layers is solder resist.

9. The wiring board according to claim 1, wherein the pads and the bonding layers have the same width at least at their boundary surfaces.

10. The wiring board according to claim 1, wherein the pads have a cylindrical external shape, and the bonding layers make contact with only the top face or the bottom face of the pads.

11. The wiring board according to claim 1, wherein a cavity is formed in each of the plurality of pads, and bonding layers are arranged in the cavity of each pad.

12. The wiring board according to claim 1, wherein the first conductive pattern is arranged in the substrate.

13. The wiring board according to claim 1, further comprising a second conductive pattern formed on a different layer from the first conductive pattern; a connection conductor electrically connecting the first conductive pattern and the second conductive pattern; a third conductive pattern formed to be contiguous to the connection conductor; and a metal layer to be a base of the third conductive pattern.

14. The wiring board according to claim 1, further comprising a second conductive pattern formed on a different layer from the first conductive pattern; and a connection conductor electrically connecting the first conductive pattern and the second conductive pattern, wherein at least one of the plurality of pads is electrically connected to the connection conductor.

15. The wiring board according to claim 14, wherein the second conductive pattern is laminated in the direction of thickness of the substrate by means of an insulation layer, and the connection conductor is formed in a via hole formed in the insulation layer.

16. The wiring board according to claim 1, wherein the plurality of pads are arranged in a peripheral array.

17. The wiring board according to claim 1, wherein solder resist is formed on each of the outermost layers on both surfaces.

18. A method for manufacturing a wiring board, comprising:
forming a first resist layer having a first opening portion and a second opening portion on a predetermined layer;
forming a conductive pattern in the first opening portion of the first resist layer and a first pad in the second opening portion of the first resist layer;
forming on the first resist layer a second resist layer which coats the conductive pattern and has an opening portion on the first pad;
forming a second pad in the opening portion of the second resist layer;
removing the first resist layer and the second resist layer;
forming a bonding layer on the second pad; and
connecting an electrode of an electronic component and the second pad electrically by means of a bonding layer.

19. The method for manufacturing a wiring board according to claim 18, wherein the bonding layer made of solder is formed by plating in the sixth step.
